(19) United States
(12) Patent Application Publication
(10) Pub. No.: US 2025/0247986 A1
(43) Pub. Date: Jul. 31, 2025

(54) WORKING ASSEMBLY AND ELECTRONIC DEVICE

(71) Applicant: CANAAN CREATIVE CO., LTD., Beijing (CN)

(72) Inventors: Shaohua ZHANG, Beijing (CN); Huan YANG, Beijing (CN); Nangeng ZHANG, Beijing (CN)

(21) Appl. No.: 19/183,765

(22) Filed: Apr. 18, 2025

Related U.S. Application Data
(63) Continuation of application No. PCT/CN2023/125750, filed on Oct. 20, 2023.

(30) Foreign Application Priority Data
Oct. 20, 2022 (CN) 202211291965.1
Nov. 11, 2022 (CN) 202211415779.4

(51) Int. Cl. H05K 7/14; G06F 1/18; H05K 1/02; H05K 7/20

(52) U.S. Cl. CPC H05K 7/1452; G06F 1/188; H05K 1/0203; H05K 7/20145

(57) ABSTRACT

A working module and an electronic device. The working module is suitable for operating in a heat-dissipating air passage, the direction from an air inlet of the heat-dissipating air passage to an air outlet thereof being a first direction. The working module comprises: a circuit board, a plurality of heat-generating components being provided on a first surface of the circuit board; and connection bases provided on the first surface of the circuit board, the connection bases being located at the edge of the circuit board. The working module can reduce the assembly time of the working module and improve the assembly efficiency of the working module.

### CROSS REFERENCE TO RELATED APPLICATIONS

This present application is a Continuation Application of International Application No. PCT/CN2023/125750, filed on Oct. 20, 2023, which claims priority to and benefits of Chinese Patent Application No. 202211291965.1, filed with the China Patent Office on Oct. 20, 2022, entitled “Working Assembly and Electronic Device”, and Chinese Patent Application No. 202211415779.4, filed with the China Patent Office on Nov. 11, 2022, entitled “Working Assembly and Electronic Device”. The entire contents of all of the above-identified applications are incorporated herein by reference.

### TECHNICAL FIELD

The present application relates to the field of heat dissipation technologies, and in particular to a working assembly and an electronic device.

### BACKGROUND

In the related art, a circuit board is typically provided with heating components including chips and a computing device typically includes a power supply module and a circuit board. The circuit board is typically provided with a plurality of connecting pieces, and the power supply module is connected to the connecting pieces by a bus bar, thereby supplying power to the circuit board.

### SUMMARY

Embodiments of the present application provide a working assembly and an electronic device.

As one aspect of the embodiments of the present application, the embodiments of the present application provide a working assembly, adapted to operating in a heat dissipation air duct, wherein a direction from an air inlet to an air outlet of the heat dissipation air duct is a first direction, the working assembly comprising: a circuit board having a first surface on which a plurality of heating components are provided; and a connecting seat provided on the first surface of the circuit board, the connecting seat being located at an edge of the circuit board.

In an implementation, the connecting seat comprises a connecting body attached to the first surface of the circuit board; and an extension connected to the connecting body and being perpendicular to the circuit board.

In an implementation, the connecting body comprises a first connecting portion extending in the first direction, and a second connecting portion connected between the first connecting portion and the extension, the second connecting portion extending in a second direction, wherein the second direction is parallel to the circuit board and perpendicular to the first direction.

In an implementation, a reinforcing rib is provided on the connecting body.

In an implementation, the reinforcing rib comprises a flange provided at an edge of the connecting body and bent towards a direction away from the circuit board.

In an implementation, the connecting seat further comprises: a limiting portion connected between the connecting body and the extension, the limiting portion and the circuit board defining a clearance groove therebetween.

In an implementation, the limiting portion comprises: a first limiting sub-portion connected to the connecting body and provided at an angle relative to the circuit board; and a second limiting sub-portion connected between the first limiting sub-portion and the extension, the second limiting sub-portion being arranged at an angle relative to the extension.

In an implementation, the extension extends beyond an end of the circuit board in a second direction, wherein the second direction is parallel to the circuit board and perpendicular to the first direction.

In an implementation, at least one positioning hole is formed on and passes through the connecting seat in a thickness direction.

In an implementation, the connecting seat comprises a connecting body attached to the first surface of the circuit board, the connecting body comprising a first connecting portion extending in the first direction and a second connecting portion extending in a second direction, wherein the at least one positioning hole is formed on the first connecting portion and the second connecting portion respectively, and the second direction is parallel to the circuit board and perpendicular to the first direction.

In an implementation, the working assembly further comprises: a first heat sink provided on the first surface of the circuit board; and a second heat sink provided on a second surface of the circuit board, the dimension of the second heat sink being larger than that of the first heat sink, wherein the second direction is parallel to the circuit board and perpendicular to the first direction.

In an implementation, in a second direction, the length of the second heat sink is larger than that of the first heat sink, wherein the second direction is parallel to the circuit board and perpendicular to the first direction.

In an implementation, in a second direction, at least one end of the second heat sink extends beyond the corresponding end of the first heat sink.

In an implementation, the first heat sink and the second heat sink each comprises a heat dissipation body and a plurality of heat dissipation fins, and the number of the heat dissipation fins of the first heat sink is smaller than the number of the heat dissipation fins of the second heat sink.

In an implementation, the first heat sink and the second heat sink each comprises a heat dissipation body and a plurality of heat dissipation fins, the density of the heat dissipation fins of the first heat sink is the same as that of the heat dissipation fins of the second heat sink, and the height of the heat dissipation fins of the first heat sink is different from that of the heat dissipation fins of the second heat sink.

As another aspect of the embodiments of the present application, the embodiments of the present application provide an electronic device, comprising the working assembly according to any one of the embodiments of the above-mentioned aspects of the present application.

In an implementation, the electronic device comprises a conductive connector and a power supply module, the conductive connector electrically connected to the power supply module and the connecting seat of the working assembly, respectively.

The above-mentioned summary is for the purpose of illustration only and is not intended to be limiting in any way. In addition to the illustrative aspects, implementations, and features described above, further aspects, implementations, and features of the present application will become readily apparent with reference to the accompanying drawings and the following detailed description.

### BRIEF DESCRIPTION OF THE DRAWINGS

In the accompanying drawings, unless otherwise specified, the same reference signs refer to the same or similar components or elements throughout the drawings. These accompanying drawings are not necessarily drawn to scale. It should be understood that these accompanying drawings only depict some implementations according to the disclosure of the present application and should not be regarded as limiting the scope of the present application.

FIG. 1 is a perspective schematic structural view of an electronic device according to an embodiment of the present application;

FIG. 2 is a perspective view of the electronic device shown in FIG. 1 from another angle;

FIG. 3 is a front view of the electronic device shown in FIG. 1;

FIG. 4 is a rear view of the electronic device shown in FIG. 1;

FIG. 5 is a left view of the electronic device shown in FIG. 1;

FIG. 6 is a right view of the electronic device shown in FIG. 1;

FIG. 7 is a top view of the electronic device shown in FIG. 1;

FIG. 8 is a bottom view of the electronic device shown in FIG. 1;

FIG. 9A is an exploded view of the electronic device shown in FIG. 1;

FIG. 9B is an enlarged view of portion A circled in FIG. 9A;

FIG. 10A is a schematic structural view of an air outlet panel according to another embodiment of the present application;

FIG. 10B is a partially enlarged view of the air outlet panel shown in FIG. 10A;

FIG. 11 is another exploded view of the electronic device shown in FIG. 1;

FIG. 12 is schematic illustration of installation of a fan assembly of the electronic device shown in FIG. 1;

FIG. 13 is a cross-sectional view of the electronic device shown in FIG. 1;

FIG. 14 is schematic illustration of cable connection of a fan module of the electronic device shown in FIG. 1;

FIG. 15 is a perspective view of the fan assembly of the electronic device shown in FIG. 1;

FIG. 16 is an enlarged view of portion B circled in FIG. 15;

FIG. 17 is a perspective view of the fan assembly of the electronic device shown in FIG. 1 from another angle;

FIG. 18 is a perspective view of a mounting member of the fan assembly shown in FIG. 17;

FIG. 19 is a perspective view of a flexible protective cover of the fan assembly shown in FIG. 17;

FIG. 20 is a schematic view of an internal structure of the electronic device shown in FIG. 1;

FIG. 21 is schematic illustration of cable connection of the electronic device shown in FIG. 1;

FIG. 22 is a schematic structural view of a first conductive connector and a second conductive connector according to an embodiment of the present application;

FIG. 23 is a cross-sectional view of an electronic device according to an embodiment of the present application;

FIG. 24 is an enlarged view of portion C circled in FIG. 23;

FIG. 25A is a cross-sectional view of an electronic device according to an embodiment of the present application;

FIG. 25B is an enlarged view of portion D circled in FIG. 25A;

FIG. 26A is a cross-sectional view of an electronic device according to an embodiment of the present application;

FIG. 26B is a partially enlarged view of the electronic device shown in FIG. 26A;

FIG. 27 is schematic illustration of installation of a power supply module according to an embodiment of the present application;

FIG. 28 is schematic illustration of installation of a power supply module from another angle according to an embodiment of the present application;

FIG. 29A is schematic illustration of connection between a power supply module and a housing according to an embodiment of the present application;

FIG. 29B is an enlarged view of portion E circled in FIG. 29A;

FIG. 30A is schematic illustration of installation of a power supply module of an electronic device according to another embodiment of the present application;

FIG. 30B is a partially enlarged view of the electronic device shown in FIG. 30A;

FIG. 30C is a schematic structural view of a threaded fastener of the electronic device shown in FIG. 30A;

FIG. 31 is a perspective schematic structural view of a working assembly according to an embodiment of the present application;

FIG. 32 is a perspective view of the working assembly shown in FIG. 31 from another angle;

FIG. 33 is a front view of the working assembly shown in FIG. 31;

FIG. 34 is a rear view of the working assembly shown in FIG. 31;

FIG. 35 is a left view of the working assembly shown in FIG. 31;

FIG. 36 is a right view of the working assembly shown in FIG. 31;

FIG. 37 is a top view of the working assembly shown in FIG. 31;

FIG. 38 is a bottom view of the working assembly shown in FIG. 31;

FIG. 39A is an exploded view of the working assembly shown in FIG. 31;

FIG. 39B is a schematic view of a working assembly according to another embodiment of the present application;

FIG. 40 is a schematic structural view of a first connecting seat of a working assembly according to an embodiment of the present application;

FIG. 41 is a schematic structural view of a first connecting seat of a working assembly according to an embodiment of the present application;

FIG. 42 is a partial schematic structural view of a sealing member of a working assembly according to an embodiment of the present application;

FIG. 43 is schematic illustration of installation of a sealing member of a working assembly according to an embodiment of the present application;

FIG. 44 is a schematic structural view of a spring screw of a working assembly according to an embodiment of the present application;

FIG. 45 is a perspective schematic structural view of a working assembly according to another embodiment of the present application;

FIG. 46 is a front view of the working assembly shown in FIG. 45;

FIG. 47 is a rear view of the working assembly shown in FIG. 45;

FIG. 48 is a left view of the working assembly shown in FIG. 45;

FIG. 49 is a right view of the working assembly shown in FIG. 45;

FIG. 50 is a top view of the working assembly shown in FIG. 45;

FIG. 51 is a bottom view of the working assembly shown in FIG. 45;

FIG. 52 is a schematic structural view of a circuit board according to an embodiment of the present application;

FIG. 53 is an enlarged view of portion F circled in FIG. 51.

### DESCRIPTION OF REFERENCE NUMERALS

100: working assembly;

110: circuit board; 111: heating component; 112: first signal socket; 120: heat sink; 121: heat dissipation body; 122: heat dissipation fin; 1221: chamfered portion; 1222: groove; 123: first heat sink; 124: second heat sink; 140: first connecting seat; 141: connecting body; 1411: flange; 142: extension; 143: clearance groove; 150: second connecting seat; 160: sealing member; 161: first sealing portion; 162: second sealing portion; 170: spring screw; 171: spring; 172: screw; 1400: connecting seat; 1422: first connecting portion; 1424: second connecting portion; 1460: limiting portion; 1462: first limiting sub-portion; 1464: second limiting sub-portion; 1480: positioning hole;

200: electronic device;

210: housing; 211: vent hole; 212: top shell; 213: air outlet panel; 214: second elastic snap; 215: second conductive foam; 220: fan assembly; 221: mounting member; 2211: threaded hole; 2212: fixing hole; 222: fan module; 230: first elastic snap; 231: connecting portion; 232: abutting portion; 240: first conductive foam; 250: flexible protective cover; 260: control panel; 261: second signal socket; 262: fan interface; 263: temperature sensor; 264: indicator lamp; 270: power supply module; 271: positioning hole; 272: through hole; 273: threaded fastener; 280: first conductive connector; 290: second conductive connector.

### DETAILED DESCRIPTION

In the following, only certain example embodiments are briefly described. As those skilled in the art will appreciate, the above-mentioned embodiments can be modified in various different ways without departing from the spirit or scope of the present application. Therefore, the accompanying drawings and the description are regarded as illustrative rather than limiting in nature.

A circuit board is typically provided with heating components including chips. The heating components may generate a large amount of heat during operation, and thus it is necessary to place the circuit board in a heat dissipation air duct for heat dissipation. However, the temperature difference between the temperature of a heating component close to an air outlet and the temperature of a heating component close to an air inlet is typically large, resulting in poor temperature uniformity among the heating components.

A computing device typically includes a power supply module and a circuit board. The circuit board is typically provided with a plurality of connecting pieces, and the power supply module is connected to the connecting pieces by a bus bar, thereby supplying power to the circuit board. However, the provision of the plurality of connecting pieces will increase the assembly time of the working assembly, thereby reducing the assembly efficiency.

By means of the technical solutions disclosed herein, the embodiments of the present application can reduce the assembly time of the working assembly, and improve the assembly efficiency of the working assembly.

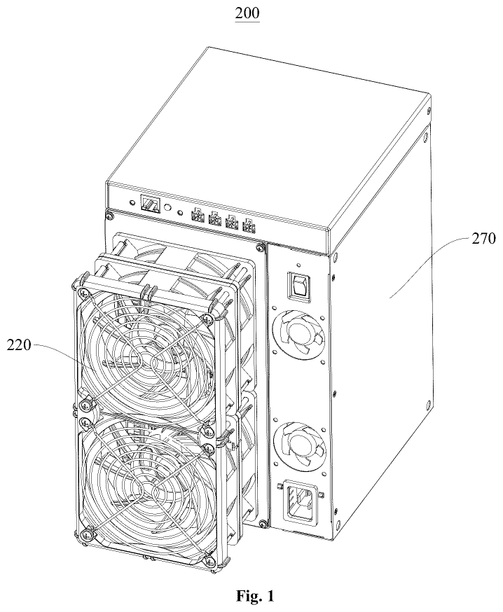

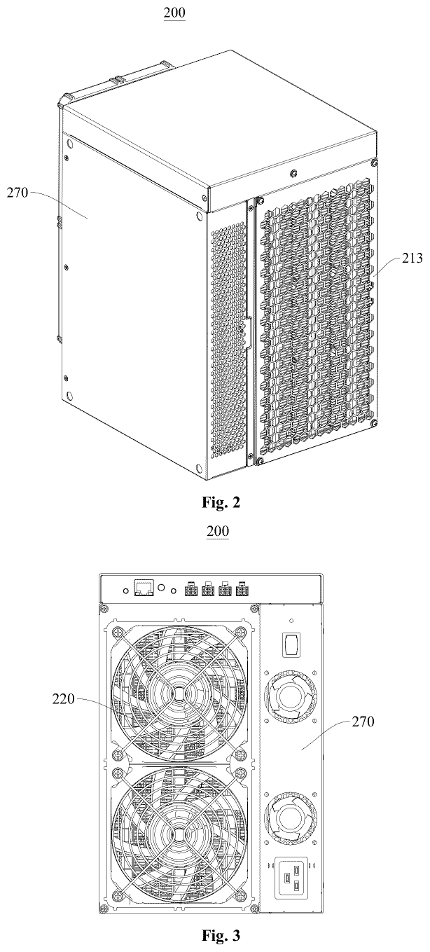

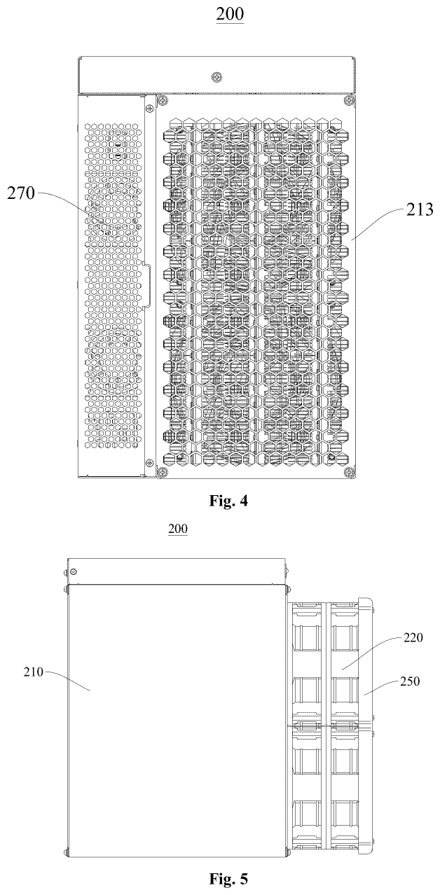

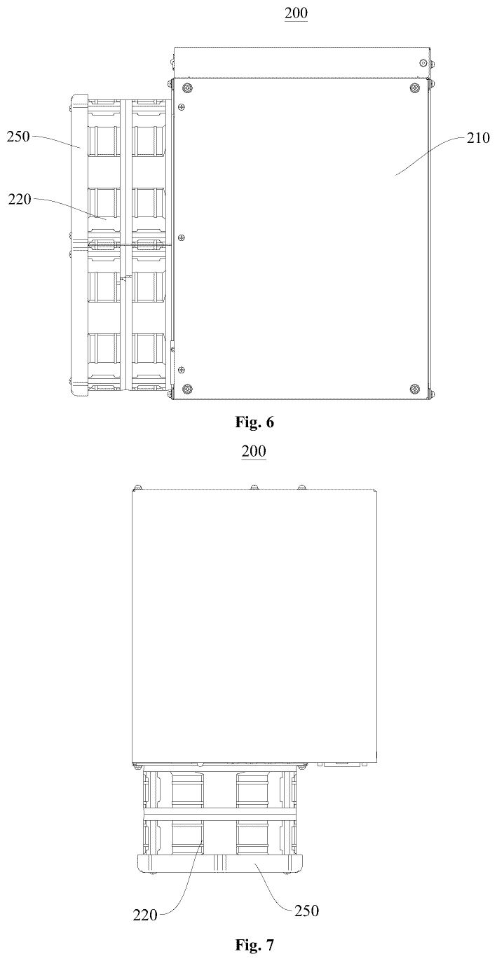

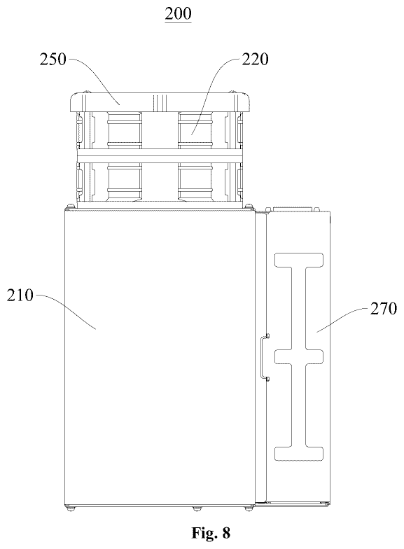

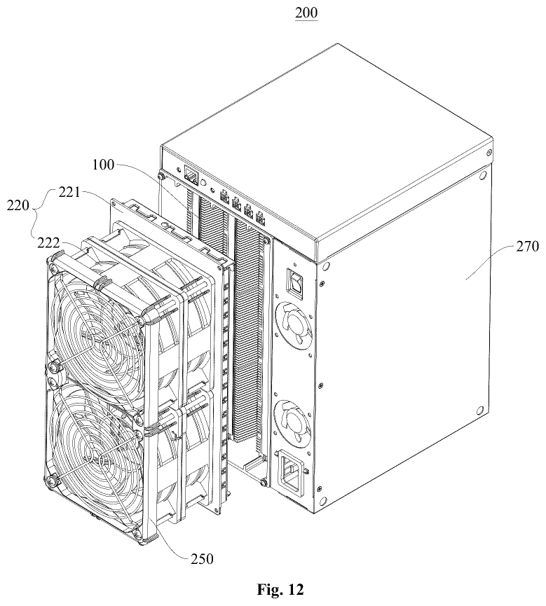

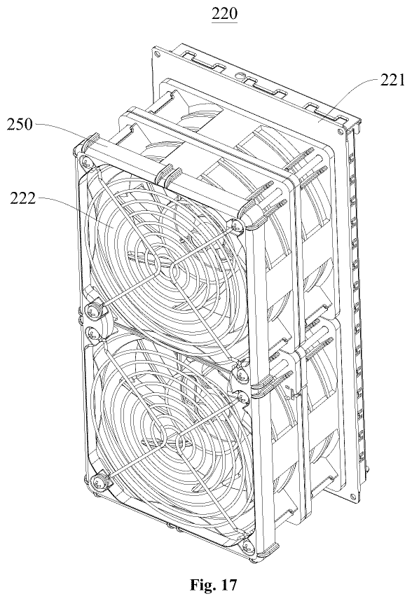

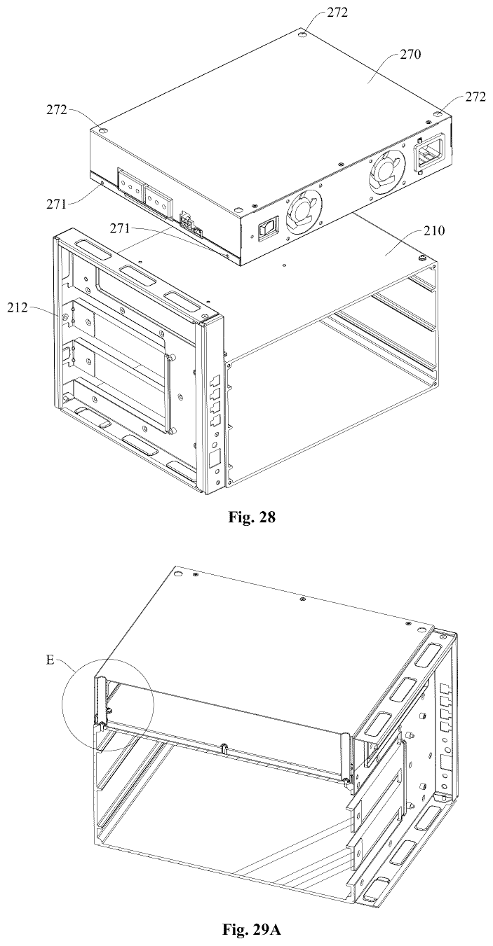

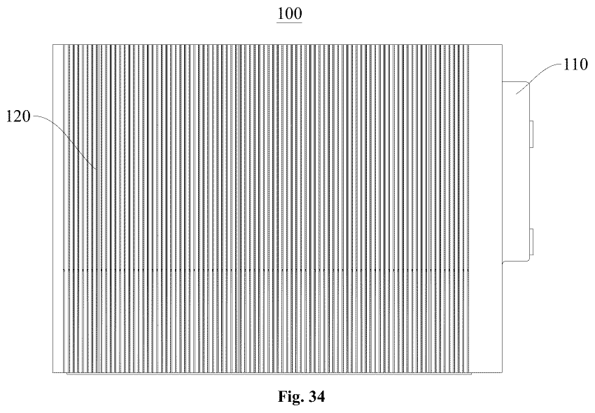

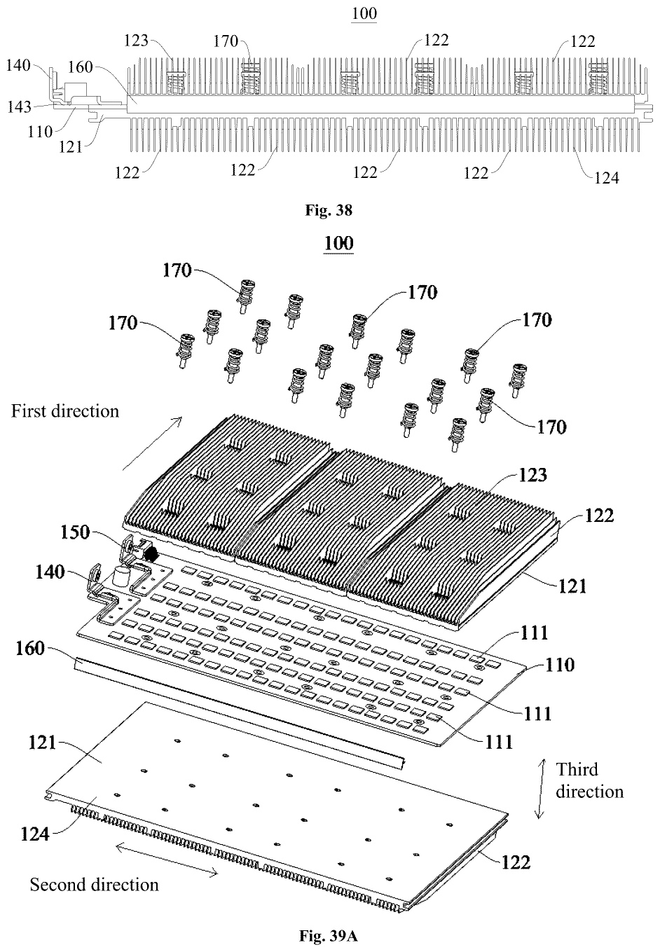

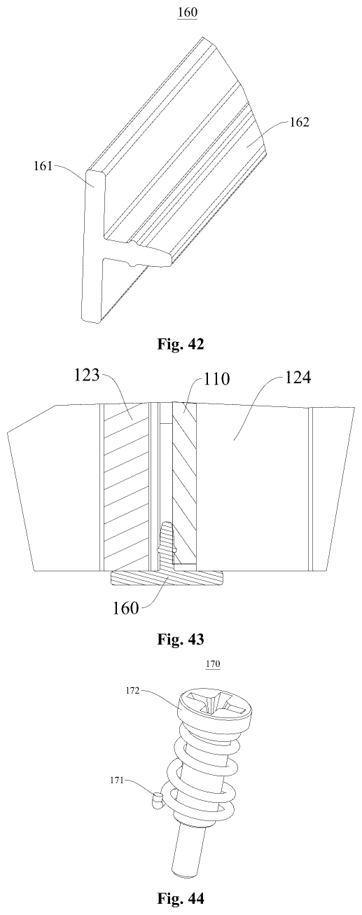

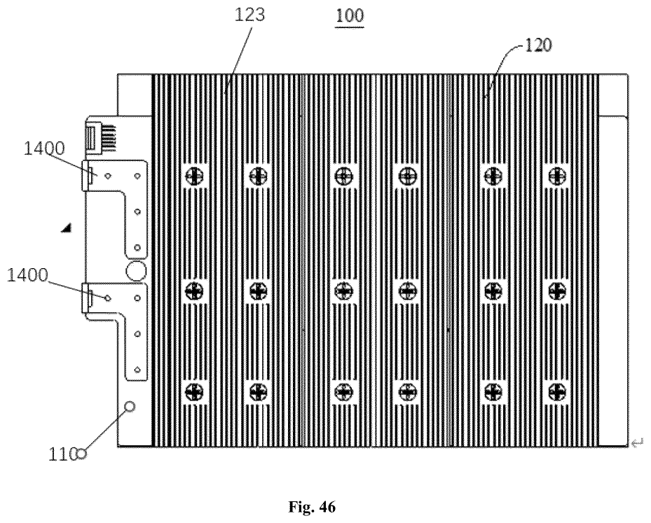

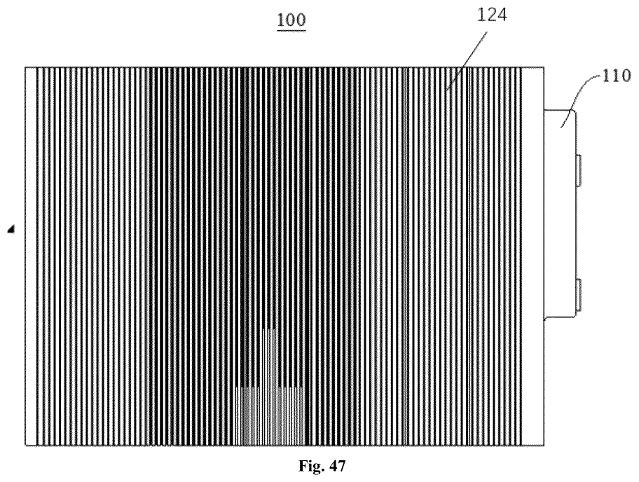

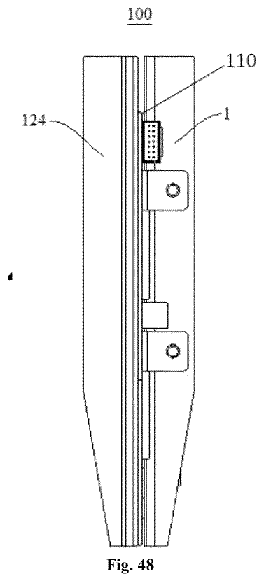

A working assembly 100 according to embodiments of a first aspect of the present application will be described in conjunction with FIGS. 1-52. The working assembly 100 is adapted to operating in a heat dissipation air duct to achieve heat dissipation of the working assembly 100.

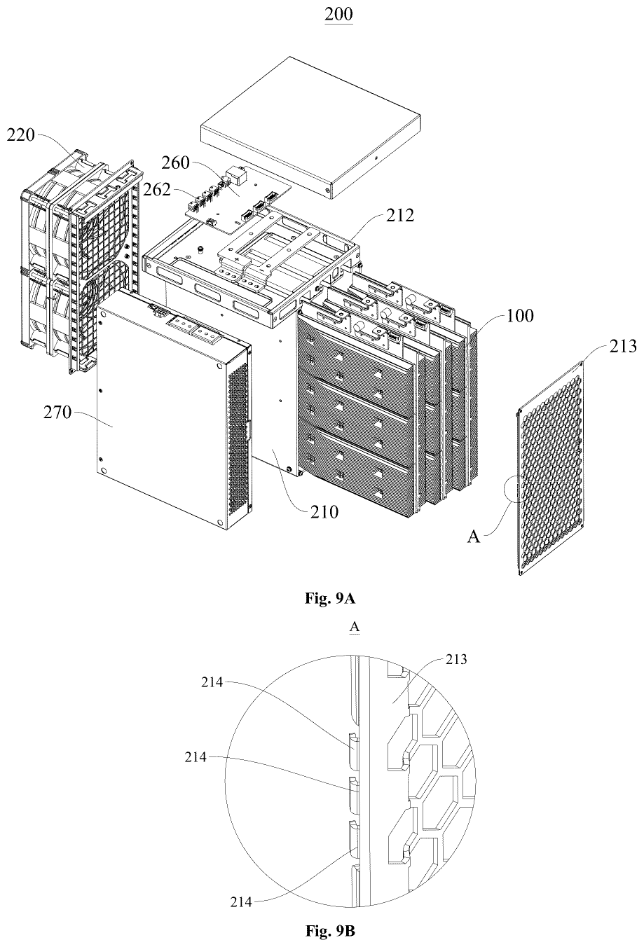

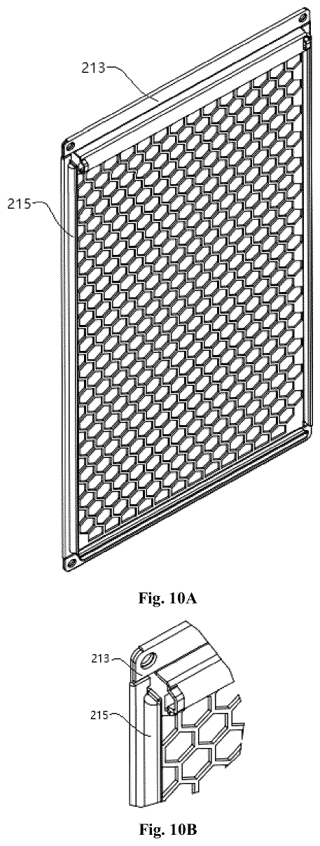

As shown in FIG. 9 and FIGS. 31-39A, the working assembly 100 comprises a circuit board 110 and at least one heat sink 120. Specifically, at least one side surface of the circuit board 110 is provided with a plurality of heating components 111, and the heat sink 120 is provided on the circuit board 110. In the description of the present application, “a plurality of” means two or more.

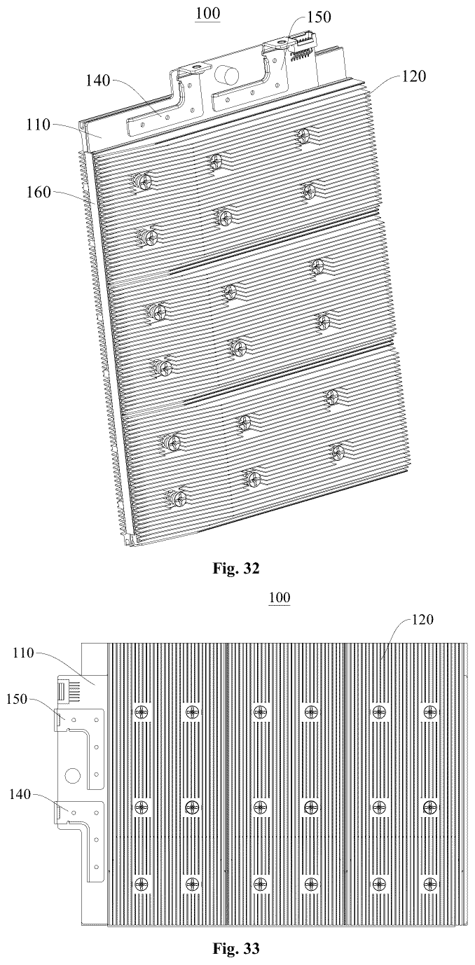

For example, two heat sinks 120 are shown in the examples of FIGS. 31-39A, with the two heat sinks 120 being a first heat sink 123 and a second heat sink 124, respectively. The first heat sink 123 is provided on a first surface of the circuit board 110, and the second heat sink 124 is provided on a second surface of the circuit board 110. The plurality of heating components 111 may include a plurality of chips provided on the first surface of the circuit board 110, the first heat sink 123 may be provided corresponding to the chips, and the first heat sink 123 may be in direct or indirect contact with the chips by means of a thermal conductive material (such as silicone grease). The first heat sink 123 is provided with a plurality of bosses, and the bosses are provided corresponding to the chips. The bosses may be arranged in a plurality of rows or a plurality of columns, each row of the plurality of rows of bosses is provided corresponding to each row of chips, and each column of the plurality of columns of bosses is provided corresponding to each column of chips. The bosses may also be arranged as independent structures in an array, each independent boss is provided corresponding to a single chip, with the cross-sectional area of each independent boss may cover a single chip, and may also be smaller than that of the single chip. The first heat sink 123 may include a plurality of sub-heat sinks provided independently of each other.

The heat of the first surface of the circuit board 110 may be effectively transferred to the first heat sink 123, the heat of the second surface of the circuit board 110 may be effectively transferred to the second heat sink 124. During the process of air being blown from an air inlet to an air outlet of a heat dissipation air duct, the heat of the first heat sink 123 and the heat of the second heat sink 124 may be effectively taken away, thereby achieving effective heat dissipation of the circuit board 110.

Two heat sinks 120 shown in FIGS. 31-39A are used for the purpose of illustration. However, after reading the technical solution of the present application, those skilled in the art will obviously understand that the solution may be applied to the technical solution of heat dissipation or heat dissipation by more heat sinks 120, which also falls within the scope of protection of the present application.

At the air outlet of the heat dissipation air duct, the dimension of the at least one heat sink 120 in a first direction is larger than that of the circuit board 110 in the first direction, the first direction being the direction from the air inlet to the air outlet of the heat dissipation air duct. An edge of the at least one heat sink 120 close to the air outlet extends beyond an edge of the circuit board 110 close to the air outlet.

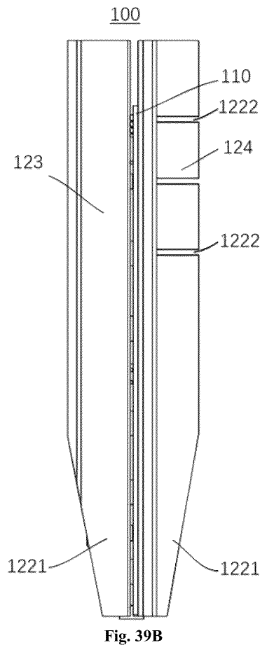

Exemplarily, the first surface and the second surface of the circuit board 110 may both be parallel to the first direction. The plurality of heating components 111 on the first surface may be arranged in columns, and in a second direction, the centers of at least three or all of the heating components 111 are located in a straight line, the second direction being perpendicular to the first direction. FIG. 39A shows six columns of heating components 111, the six columns of heating components 111 may be divided into two portions, with each of which including three columns of heating components 111, one of the two portions is arranged close to the air inlet, and the other of the two portions is arranged close to the air outlet. Edges of the first heat sink 123 and the second heat sink 124 close to the air outlet may both extend beyond the edge of the circuit board 110 close to the air outlet. With such a configuration, the area of the heat sink 120 at the air outlet may be increased, such that the heat of a group of heating components 111 close to the air outlet can be better transferred to the corresponding heat sink 120, which reduces the maximum temperature difference among the three columns of heating components 111 close to the air outlet and can improve the heat dissipation effect of the three columns of heating components 111 close to the air outlet, facilitating reduction of the maximum temperature difference between the two groups of heating components 111, thereby improving the overall temperature uniformity of the plurality of heating components 111.

According to the working assembly 100 of the embodiments of the present application, the dimension of at least one heat sink 120 close to the air outlet in the first direction may be elongated, thereby reducing the maximum temperature difference between heating components 111 close to the air outlet and heating components 111 close to the air inlet, and thereby improving the temperature uniformity of the heating components 111.

In an implementation, in the first direction, the dimension of the heat sink 120 exceeds that of the circuit board 110 by 10 mm to 20 mm (including endpoint values). Specifically, for example, the dimension of the heat sink 120 exceeds that of the circuit board 110 by L; when L<10 mm, at the air outlet of the heat dissipation air duct, the dimension of the heat sink 120 exceeding the circuit board 110 in the first direction is too small, which results in a poor heat dissipation effect of the heating components 111 close to the air outlet and fails to effectively improve the temperature uniformity of the heating components 111; and when L>20 mm, the dimension of the heat sink 120 exceeding the circuit board 110 in the first direction is too large, and the occupied space of the heat sink 120 at the air outlet is too large, which increases the volume of a housing 210 and results in an excessive weight of the heat sink 120.

Thus, by making 10 mm≤L≤20 mm, the end portion of the heat sink 120 extending beyond the circuit board 110 close to the air outlet has a reasonable dimension, thereby effectively improving the temperature uniformity of the heating components 111, while reducing the overall occupied space of the working assembly 100, and avoiding an excessive weight of the working assembly 100. Optionally, L may be 15 mm, but this is not limited thereto. Those skilled in the art will understand that “the dimension of the heat sink 120 exceeds that of the circuit board 110 by L”, which is not limited to the range of 10 mm≤L≤20 mm, and when there is a need to increase heat dissipation of the circuit board or the second half of a heat source, the method for extending the length of the heat sink of the present invention may be applied to adaptively adjust the length L according to different usage scenarios.

In an implementation, in conjunction with FIGS. 39A and 39B, each heat sink 120 includes a heat dissipation body 121 and a plurality of heat dissipation fins 122 provided on the heat dissipation body 121, wherein the heat dissipation body 121 is parallel to the circuit board 110, the heat dissipation fins 122 are perpendicular to the circuit board 110, and at least one groove 1222 is formed on at least one heat dissipation fin 122.

In an example, each groove 1222 may pass through the corresponding heat dissipation fin 122 in the second direction and a third direction to divide the heat dissipation fin 122 into a plurality of sub-heat dissipation fins. The formula for calculating the convective thermal resistance between the heat dissipation fin 122 and the air environment is given by: R=1/(hA), where R is the convective thermal resistance between the heat dissipation fin and the air environment, h is the convective heat transfer coefficient, and A is the heat dissipation area. The groove 1222 may divide the entire heat dissipation fin 122 into a plurality of sub-heat dissipation fins arranged at intervals in the first direction, air first expands and then contracts when flowing through this region, which leads to a stronger disturbance after passing through the region of the groove 1222, increasing the convective heat transfer coefficient, thereby reducing the thermal resistance.

In an example, at least one groove 1222 does not entirely pass through the corresponding heat dissipation fin 122 in the second direction and/or the third direction, and in this case, the heat dissipation fin 122 is not divided into a plurality of sub-fins. The second direction is the arrangement direction of the plurality of heat dissipation fins 122, and the third direction is the direction perpendicular to the surface of the circuit board 110.

Thus, by providing the above-mentioned grooves 1222, the overall weight of the heat dissipation fins 122 may be reduced, and the air resistance of air flowing through the heat sink 120 may be effectively reduced, increasing the ventilation volume, thereby improving the heat dissipation effect, while reducing the amount of dust accumulated on the heat dissipation fins 122. Specifically, the amount of dust accumulated on the side of the heat sink 120 close to the air inlet is typically larger than that on the side close to the air outlet. In a case where the grooves 1222 are arranged at the end of the heat dissipation fins 122 close to the air inlet, the amount of dust accumulated at the end of the heat sink 120 close to the air inlet may be further increased. By arranging the grooves 1222 at the end of the heat dissipation fins 122 close to the air outlet, it is possible to avoid increasing the amount of dust accumulated at the air inlet of the heat sink 120, thereby improving the local heat dissipation effect of the heat sink 120.

In an implementation, the grooves 1222 are arranged at an end of the heat dissipation fins 122 close to the air outlet relative to the center of the heat sink 120, i.e., “the end close to the air outlet” referring to an end close to the air outlet by using the center of the heat sink 120 as a reference. Thus, since the temperature of the air at the air outlet is typically relatively high, after the air exchanges heat with the end of the heat sink 120 close to the air outlet, the heat generated by the heating components 111 during operation cannot be effectively taken away. By arranging the grooves 1222 close to the air outlet, the convective heat transfer coefficient in the region at the air outlet may be increased, and the thermal resistance at the air outlet may be reduced, thereby increasing the ventilation volume at the air outlet, improving the heat dissipation effect of the heating components 111 at the air outlet, while suppressing dust accumulation, and further improving the temperature uniformity of the heating components 111.

In an implementation, the grooves 1222 are provided corresponding to the heating components 111. Exemplarily, each heat dissipation fin 122 of at least one heat sink 120 is provided with grooves 1222, a plurality of grooves 1222 are arranged in columns, and at least one column of grooves 1222 are provided opposite at least one column of heating components 111. For example, the grooves 1222 on a plurality of heat dissipation fins 122 may correspond to each other in the arrangement direction of the heat dissipation fins 122, so that the grooves 1222 on the plurality of heat dissipation fins 122 are arranged in columns. Only each heat dissipation fin 122 of the first heat sink 123 may be provided with grooves 1222, as shown in FIG. 39B. Alternatively, only each heat dissipation fin 122 of the second heat sink 124 may be provided with grooves 1222. Alternatively, each heat dissipation fin 122 of the first heat sink 123 and the second heat sink 124 may be provided with grooves 1222, and in this case, the grooves 1222 on each heat dissipation fin 122 of the first heat sink 123 and the second heat sink 124 may be different.

Optionally, the dimensions of the grooves 1222 in the first direction may be 2.5 mm to 3.5 mm (including the endpoint values). However, those are not limited thereto. For example, when the dimensions of the grooves 1222 in the first direction are smaller than 2.5 mm, the widths of the grooves 1222 are too small, which may result in a poor weight reduction effect. When the dimensions of the grooves 1222 in the first direction are larger than 3.5 mm, the widths of the grooves 1222 are too large, which may result in a too small surface area of the heat dissipation fin 122, thereby reducing the heat dissipation effect. By making the dimensions of the grooves 1222 in the first direction 2.5 mm to 3.5 mm, the heat dissipation effect of the heat sink 120 can be ensured, while effectively reducing the weight of the heat sink 120.

Exemplarily, in the first direction, the dimensions of the grooves 1222 on each heat dissipation fin 122 may gradually increase. Alternatively, in the first direction, the dimensions of the grooves 1222 on each heat dissipation fin 122 may gradually decrease. Alternatively, in the first direction, the dimensions of the grooves 1222 on each heat dissipation fin 122 may be completely equal. It is also possible that the dimensions of the grooves 1222 are positively or negatively correlated with the width of the heat dissipation fin 122. Of course, the present application is not limited thereto. For example, the dimensions of the grooves 1222 on each heat dissipation fin 122 may be set as required, which vary in combination with the width of the heat dissipation fin between two grooves 1222. It should be understood that the dimensions, quantity, and specific positions of the grooves 1222 on each heat dissipation fin 122 may be specifically set according to actual requirements to better meet actual applications.

Thus, by making the grooves 1222 correspond to the positions of the heating components 111, the heat generated by the heating components 111 opposite the grooves during operation may be transferred to the heat dissipation body 121, the air flowing through the heat dissipation body 121 may directly exchange heat with the heat dissipation body 121 to achieve heat dissipation of the heating components 111. Since the convective heat transfer coefficient at the grooves 1222 is large, the air resistance can be effectively reduced, thereby increasing the air volume at the heating components 111 opposite the grooves 1222, and improving the heat dissipation effect of the heating components 111 opposite the grooves 1222.

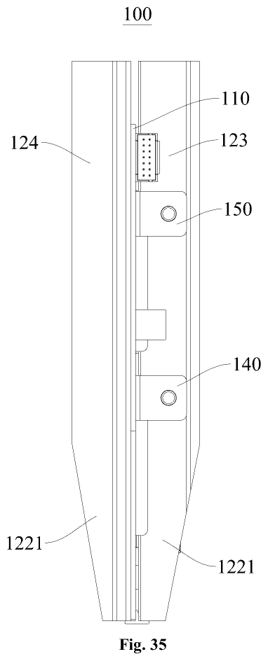

In an implementation, in conjunction with FIGS. 35, 36 and 39A, at least one heat dissipation fin 122 includes a chamfered portion 1221, the height of the chamfered portion 1221 gradually increasing in the first direction.

In an implementation, the end of the chamfered portion 1221 away from the air inlet corresponds to the position of the third column of heating components 111. The above-mentioned “third column of heating components 111” refer to the heating components located in the third column in the first direction. For example, in the examples of FIGS. 35, 36 and 39A, all the heat dissipation fins 122 of the first heat sink 123 and the second heat sink 124 include chamfered portions 1221, the chamfered portions 1221 being arranged close to the air inlet. The circuit board 110 is totally provided with six columns of heating components 111, and in the first direction, the first three columns of heating components 111 may be provided opposite the chamfered portions 1221, and the last three columns of heating components 111 may be provided opposite the corresponding grooves 1222.

Thus, by providing the above-mentioned chamfered portions 1221, the overall weight of the heat dissipation fins 122 can be effectively reduced, and the thermal resistance at the air inlet can be reduced, thereby increasing the ventilation volume at the air inlet, improving the heat dissipation effect of the heating components 111 at the air inlet, while suppressing dust accumulation, and improving the temperature uniformity of the heating components 111.

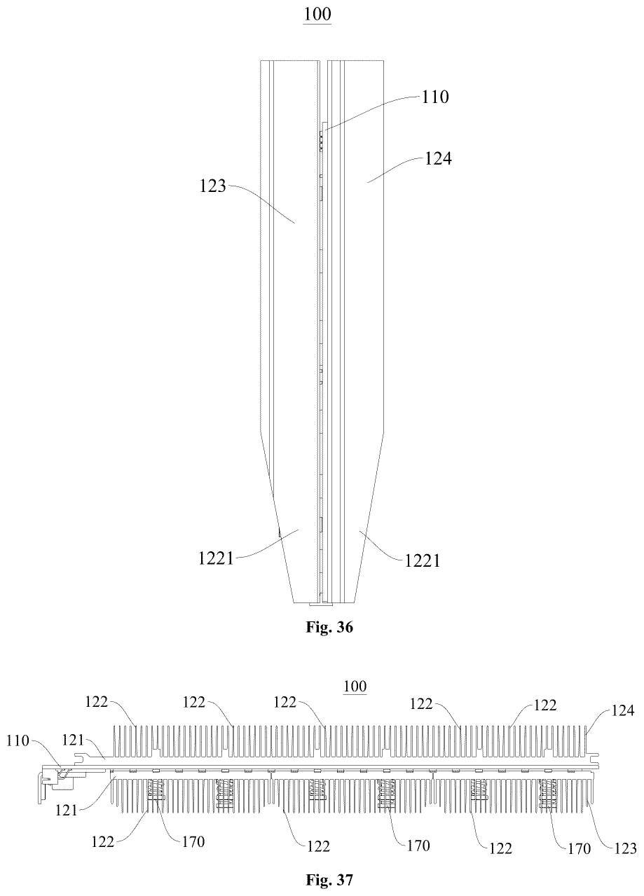

In an implementation, as shown in FIGS. 35 and 36, in the first direction, the dimension of the first heat sink 123 is the same as that of the second heat sink 124. With such a configuration, the dimensions of the first heat sink 123 and the second heat sink 124 may be consistent, while achieving heat dissipation of the first surface and the second surface of the circuit board 110, thereby improving the universality of the heat sink 120, and facilitating processing of the heat sink 120.

In an implementation, the density of the heat dissipation fins 122 of the first heat sink 123 is the same as that of the heat dissipation fins 122 of the second heat sink 124, and the height of the heat dissipation fins 122 of the first heat sink 123 is different from that of the heat dissipation fins 122 of the second heat sink 124. For example, the height of the heat dissipation fins 122 of the first heat sink 123 may be larger than that of the heat dissipation fins 122 of the second heat sink 124. Since the first heat sink 123 is in contact with a plurality of heating components 111, by making the height of the heat dissipation fins 122 of the first heat sink 123 larger than that of the heat dissipation fins 122 of the second heat sink 124, the area of the heat dissipation fins 122 of the first heat sink 123 may be larger than that of the heat dissipation fins 122 of the second heat sink 124, and the heat dissipation fins 122 of the first heat sink 123 can effectively absorb the heat generated by the plurality of heating components 111 during operation, thereby improving the heat dissipation effect.

In another implementation, the height of the heat dissipation fins 122 of the first heat sink 123 is the same as that of the heat dissipation fins 122 of the second heat sink 124, and the density of the heat dissipation fins 122 of the first heat sink 123 is different from that of the heat dissipation fins 122 of the second heat sink 124. For example, the density of the heat dissipation fins 122 of the first heat sink 123 may be larger than that of the heat dissipation fins 122 of the second heat sink 124. Since the first heat sink 123 is in contact with a plurality of heating components 111, by making the density of the heat dissipation fins 122 of the first heat sink 123 larger than that of the heat dissipation fins 122 of the second heat sink 124, the area of the heat dissipation fins 122 of the first heat sink 123 may be larger than that of the heat dissipation fins 122 of the second heat sink 124, and the heat dissipation fins 122 of the first heat sink 123 can also effectively absorb the heat generated by the plurality of heating components 111 during operation, thereby improving the heat dissipation effect. Alternatively, the density of the heat dissipation fins 122 of the first heat sink 123 may be smaller than that of the heat dissipation fins 122 of the second heat sink 124. In this way, there is a larger heat dissipation space between adjacent heat dissipation fins 122 of the first heat sink 123, and the first heat sink 123 shares more air, thereby reducing the air resistance, increasing the ventilation volume, improving dust accumulation, and also effectively dissipating the heat generated by the plurality of heating components 111 during operation.

In an optional implementation, the total surface area of the heat dissipation fins 122 of the first heat sink 123 is larger than that of the heat dissipation fins 122 of the second heat sink 124. In this way, it is advantageous to reduce the overall temperature of the plurality of heating components 111 and reduce the maximum temperature of the plurality of heating components 111.

Of course, the present application is not limited thereto. In another optional implementation, the total surface area of the heat dissipation fins 122 of the first heat sink 123 may be smaller than that of the heat dissipation fins 122 of the second heat sink 124. In this way, the dust accumulation amount of the first heat sink 123 can be further improved, thereby effectively dissipating the heat generated by the plurality of heating components 111 during operation.

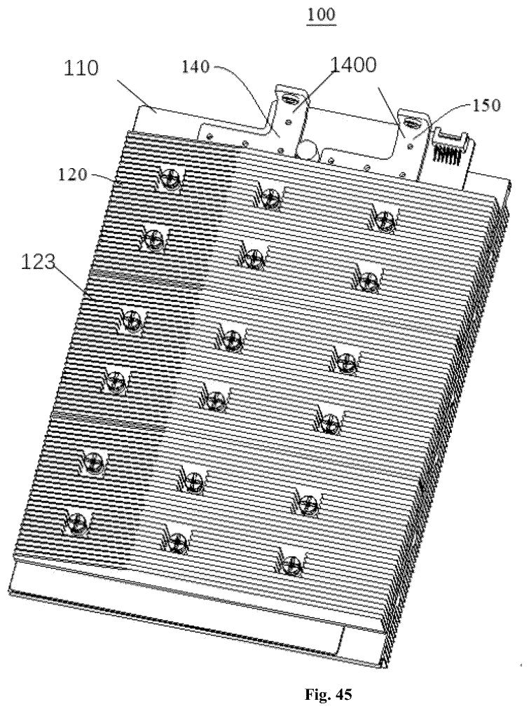

In an implementation, as shown in FIG. 45-51, the number of heat dissipation fins 122 of the first heat sink 123 may be smaller than the number of heat dissipation fins 122 of the second heat sink 124. In this way, the total surface area of the heat dissipation fins 122 of the first heat sink 123 may be relatively small, thereby increasing the ventilation volume, improving dust accumulation, and also effectively dissipating the heat generated by the plurality of heating components 111 during operation.

In an implementation, with reference to FIGS. 45-51, in the second direction, an end of the second heat sink 124 extends beyond the corresponding end of the first heat sink 123. For example, in the examples of FIGS. 45-51, in the second direction, the dimension of the second heat sink 124 is larger than that of the first heat sink 123, and two ends of the second heat sink 124 extend beyond the corresponding ends of the first heat sink. With such a configuration, the number of heat dissipation fins 122 of the second heat sink 124 is relatively large, and the total surface area of the heat dissipation fins 122 is relatively large, allowing the heat generated by the circuit board 110 during operation to be effectively discharged by the heat dissipation fins 122 of the second heat sink 124. Meanwhile, the number of first heat sinks 123 may be relatively small, and the total surface area of the heat dissipation fins 122 is relatively small, which can further alleviate the problem of serious dust accumulation of the first heat sink 123 and increases the ventilation volume of the first heat sink 123, thereby further improving the heat dissipation effect.

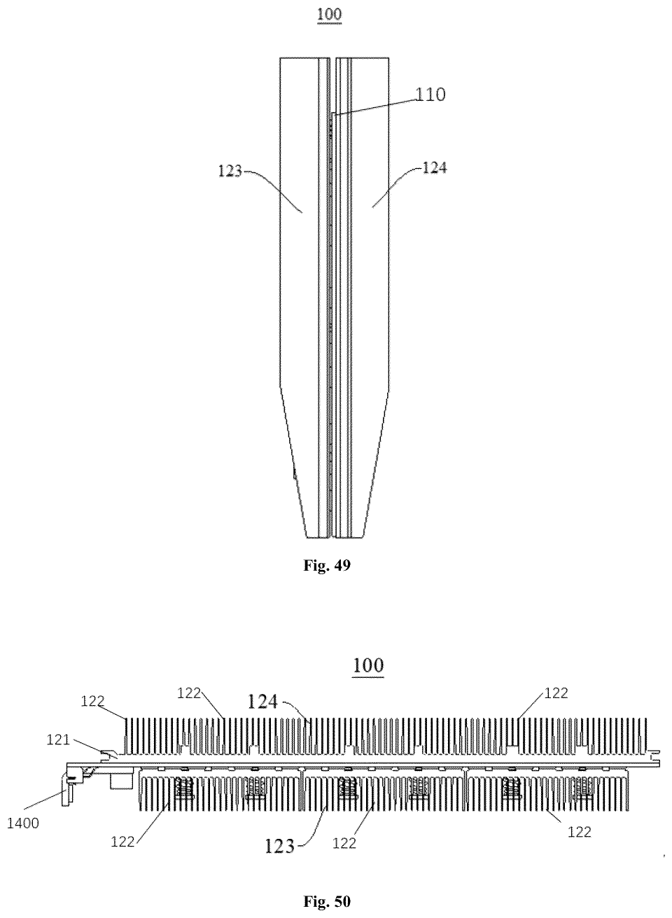

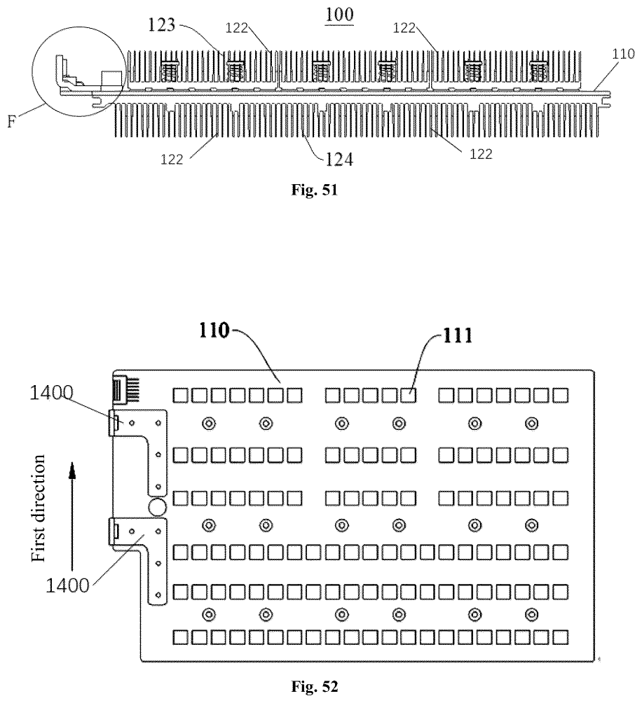

In an implementation, with reference to FIGS. 50 and 51, the first heat sink 123 and the second heat sink 124 each includes a heat dissipation body 121 and a plurality of heat dissipation fins 122, and the number of heat dissipation fins 122 of the first heat sink 123 is smaller than that of the heat dissipation fins 122 of the second heat sink 124. For example, the first heat sink 123 may include three sub-heat sinks provided independently of each other in the second direction. The number of heat dissipation fins 122 of each sub-heat sink may be 29, and thus the number of heat dissipation fins 122 of the first heat sink 123 is 87. The number of heat dissipation fins 122 of the second heat sink 124 may be 91.

In this embodiment, the number of heat dissipation fins 122 of the first heat sink 123 may be relatively small, so that the total surface area of the heat dissipation fins 122 of the first heat sink 123 may be relatively small, thereby increasing the ventilation volume, improving dust accumulation, and also effectively dissipating the heat generated by the plurality of heating components 112 during operation.

In an implementation, the plurality of heating components 112 may constitute a plurality of heating columns arranged at intervals in the first direction, and the number of heating components 112 in at least one heating column close to the air inlet is larger than the number of heating components 112 in at least one heating column close to the air outlet, that is, the density of the heating components 111 close to the air inlet of the heat dissipation air duct may be larger than that of the heating components 111 close to the air outlet. Since the air entering from the air inlet is cold air and the air discharged from the air outlet is hot air, by making the density of the heating components 111 at the air inlet larger, the heat generated by the heating components 111 at the air inlet may be increased, and by making the density of the heating components 111 at the air outlet smaller, the heat generated by the heating components 111 at the air outlet may be reduced, so that the maximum temperature difference between the heating components 111 close to the air outlet and the heating components 111 close to the air inlet can be further reduced, thereby improving the temperature uniformity of the heating components 111.

In an implementation, as shown in FIG. 52, the plurality of heating components 111 close to the air outlet are divided into a plurality of heating component groups in the second direction, and the gap between two adjacent heating component groups is larger than the gap between two adjacent heating components 111 in each heating component group.

For example, six columns of heating components 111 are shown in the example of FIG. 52. For the convenience of description, the six columns of heating components 111 sequentially arranged in the first direction are referred to as a first heating column, a second heating column, . . . , and a sixth heating column, respectively. The number of heating components 111 in each of the first to third heating columns is 21, and the number of heating components 111 in each of the fourth to sixth heating columns is 19. The 21 heating components 111 in each of the first to third heating columns are uniformly arranged at intervals. The 19 heating components 111 in each of the fourth to sixth heating columns are divided into three heating component groups, and in the three heating component groups, the numbers of heating components 111 in heating component groups at two ends in the second direction are the same, and the number of heating components 111 in a heating component group at the middle in the second direction is smaller than those of the heating components 111 in the heating component groups at two ends.

In this embodiment, there may be a relatively large heat dissipation gap between two adjacent heating component groups at the air outlet, so that the temperature close to the air outlet can be reduced, and the maximum temperature difference between the air inlet and the air outlet can be further reduced, thereby improving the temperature uniformity of the working assembly 100.

In an implementation, the arrangement method of the heating components 111, such as a chip array, may have a plurality of forms. From the first column close to the air inlet (such as the above first heating column) to the last column close to the air outlet (such as the above sixth heating column), the numbers of chips in respective columns are not completely equal. The numbers of chips in respective columns may gradually decrease, such as 21, 20, 19, 18, 17, 16; they may partially decrease, such as 21, 21, 21, 19, 19, 19; or they may also jump in number, such as 21, 21, 20, 19, 20, 21, or 21, 21, 20, 19, 18, 21. It is also possible to set other numbers of chip array according to heat dissipation requirements, so that the total number of chips in the first half close to the air inlet is larger than the total number of chips in the second half close to the air outlet. The first half and the second half herein may either be formed by dividing the number of columns of chips in half, or by dividing the dimension of the circuit board 110 in half. As shown in FIG. 52, the total number of first three columns of chips close to the air inlet is larger than the total number of last three columns of chips close to the air outlet.

Due to the variation in the number of chips in each column, the arrangement of chips in each row may also take various forms, and the number of chips in each row may be different. For example, some rows of chips are arranged in a straight line based on the central points of chips, while the central points of some rows of chips do not form a straight line, such as a stepped arrangement (e.g., in line with the above-mentioned “the numbers of chips in respective columns may gradually decrease, such as 21, 20, 19, 18, 17, 16”, forming a stepped arrangement in the row direction). The number of chips in each row is also different in embodiments, for example, in the second direction, the numbers of chips in rows close to two ends of the circuit board 110 are larger than those of chips in rows close to the center of the circuit board 110. In short, the total chip distribution and/or quantity is divided into various portions, and the total number of chips in the divided portions meets preset distribution requirements.

Specifically, in the second direction, by using the number of chips in the first heating column as a division basis, the circuit board 110 is divided into three portions from left to right, i.e., a first portion, a second portion and a third portion, wherein the total number of chips in the first portion or the third portion close to two ends of the circuit board 110 is larger than that in the second portion in the middle. In another embodiment, if in the second direction, by using the number of chips in the first heating column as a division basis, the circuit board 110 is divided into two portions from left to right, the number of chips in the first portion is smaller than or equal to that in the second portion.

With reference to FIG. 52, the above-mentioned specific division is made in the second direction by using the number of chips in the first heating column as a division basis. In an implementation, the division method is average division, the circuit board 110 is divided into three portions from left to right. The first heating column totally has 21 chips, wherein the circuit board 110 is divided into three portions from left to right, with every 7 chips in the first heating column corresponding to one of the divided portions, the total number of chips in the first portion is 42, the total number of chips in the second portion is 36, and the total number of chips in the third portion is 42. The total number of chips in the first portion (42) or the third portion (42) close to two ends of the circuit board 110 is larger than the total number (36) in the second portion in the middle. If in the second direction, by using the number of chips in the first heating column as a division basis, the circuit board 110 is divided into two portions from left to right, the central axis of the 11th chip in the middle of the first heating column may be used as a division point to divide the circuit board 110 into two portions from left to right, the number of chips in the first portion (57) is equal to that in the second portion (57). Those skilled in the art will understand that the division method is not limited to the disclosure, and when the total number of chips in the first heating column is odd or even, the division method may be flexibly selected. Of course, the division may also be based on the overall area formed by the edges of the chips arranged on the circuit board, which may be average division. Of course, the division may also be made according to other proportions, so that the total number of chips in each portion meets preset distribution requirements.

In summary, the arrangement method of the chips may be set according to heat dissipation conditions at various positions in the air duct. For example, the air inlet has a low ambient temperature and a high overall heat dissipation efficiency, more chips may be arranged. The air outlet has a high ambient temperature and a low overall heat dissipation efficiency, fewer chips may be arranged, enabling the total number of chips close to the air outlet to be smaller than that of chips close to the air inlet. In addition, in the direction perpendicular to the air, the temperatures at the upper and lower ends of the circuit board 110 are lower than the temperature at the center of the circuit board 110, more chips may be arranged at two ends, and fewer chips may be arranged at the center, enabling the total number of chips at two ends to be larger than that of chips at the center. Alternatively, after the circuit board is divided into two portions, the total number of chips at the lower half is larger than that of chips at the upper half. This design concept is completely different from typically concept of changing the thermal resistance of the heat sink to achieve uniform temperature distribution.

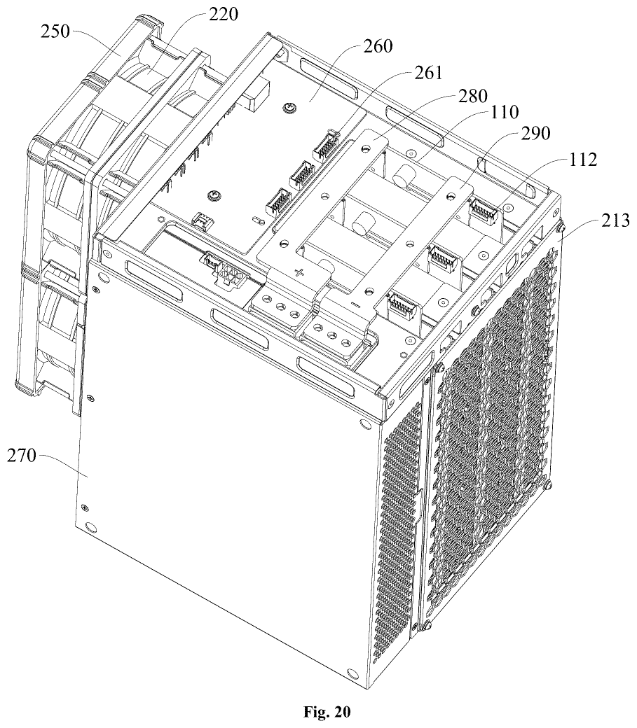

As shown in FIGS. 20, 45, 46, 40, 42, 50 and 51-53, the working assembly 100 includes a circuit board 110 and a connecting seat 1400. Specifically, a plurality of heating components 112 are provided on a first surface of the circuit board 110. The connecting seat 1400 is provided on the first surface of the circuit board 110, and the connecting seat 1400 is located at one end of the plurality of heating components 112 in a second direction, wherein the second direction is parallel to the circuit board 110 and perpendicular to the first direction. In the description of the present application, “a plurality of” means two or more.

Exemplarily, the connecting seat 1400 may be an aluminum seat or a copper seat, and the thickness may be greater if the connecting seat 1400 is an aluminum seat than if it is a copper seat. The connecting seat 1400 may be welded to the first surface of the circuit board 110.

Exemplarily, in conjunction with FIG. 20, the number of connecting seats 1400 may be two, and the two connecting seats 1400 are provided at intervals in the first direction. The electronic device 200 may include two conductive connectors 280, 290. A part of each of the conductive connectors 280, 290 may be electrically connected to a power supply module 270 of the electronic device 200, and the other part of each of the conductive connectors 280, 290 may be electrically connected to a corresponding connecting seat 1400 to achieve electrical connection between the power supply module 270 and the circuit board 110. Current may flow from the power supply module 270 through the conductive connectors 280, 290 and the connecting seats 1400 and then be input in the circuit board 110 to achieve power supply to the circuit board 110 by the power supply module 270. The two conductive connectors 280, 290 may be a positive bus bar and a negative bus bar, respectively.

By being provided with the above-mentioned connecting seat 1400, the working assembly 100 according to the embodiments of the present application, compared with the method of providing a plurality of connecting pieces in the prior art, makes the structure of the connecting seat 1400 simpler to facilitate processing, while achieving the electrical connection between the power supply module 270 and the circuit board 110, which can effectively improve the assembly efficiency of the working assembly 100.

Specifically, with reference to FIG. 31 and FIGS. 39A-42, the end of the circuit board 110 in the second direction is provided with a first connecting seat 140 and a second connecting seat 150, and the first connecting seat 140 and the second connecting seat 150 are spaced apart in the first direction, the second direction being perpendicular to the first direction. For example, the first connecting seat 140 and the second connecting seat 150 may be made of aluminum or copper, and the thickness of the connecting seats when made of aluminum may be larger than the thickness of the connecting seats when made of copper. Thus, by providing the first connecting seat 140 and the second connecting seat 150, compared with the method for providing a plurality of connecting pieces in the prior art, the structures of the first connecting seat 140 and the second connecting seat 150 are simpler, facilitating processing, thereby effectively improving the assembly efficiency of the working assembly 100.

Further, as shown in FIGS. 39A-42, the first connecting seat 140 and the second connecting seat 150 each include a connecting body 141 and an extension 142. The connecting body 141 is connected to the first surface of the circuit board 110, and the extension 142 is connected to the connecting body 141 and connected with the circuit board 110 at an angle, that is, the extension 142 is connected with the circuit board 110, and the two are at a certain angle, the degree of which is not specifically limited and may be set according to actual conditions. Preferably, the extension 142 is perpendicular to the circuit board 110. For example, in the example of FIG. 20, bottom surfaces of the conductive connectors 280, 290 may be in contact with top surfaces of the extensions 142, and threaded fasteners may pass through the conductive connectors 280, 290 to connect with the corresponding extensions 142. That is, one end of the extension 142 is connected to the connecting body 141, and the other end of the extension 142 extends away from the circuit board 110 in the third direction, the third direction being perpendicular to the first surface.

For example, the extension 142 may include a first connecting segment, a second connecting segment, and a third connecting segment. One end of the first connecting segment may be connected to the connecting body 141, and the other end of the first connecting segment may be provided at an angle towards a direction away from the circuit board 110. Providing the same at an angle may include providing the same perpendicularly and providing the same inclinedly. One end of the second connecting segment may be connected to the other end of the first connecting segment, and the second connecting segment may be set far away from the first connecting segment in the direction parallel to the first surface. One end of the third connecting segment may be connected to the other end of the second connecting segment, and the other end of the third connecting segment may be set far away from the circuit board 110 in the direction perpendicular to the first surface.

Thus, by providing the above connecting body 141 and extension 142, the connecting body 141 may achieve secure connection between the entire connecting seat (i.e., the first connecting seat 140 and the second connecting seat 150) and the circuit board 110, and the extension 142 may extend outwards to be connected to a conductive connector, thereby making the electrical connection between the power supply module 270 and the circuit board 110, and achieving power supply for the circuit board 110.

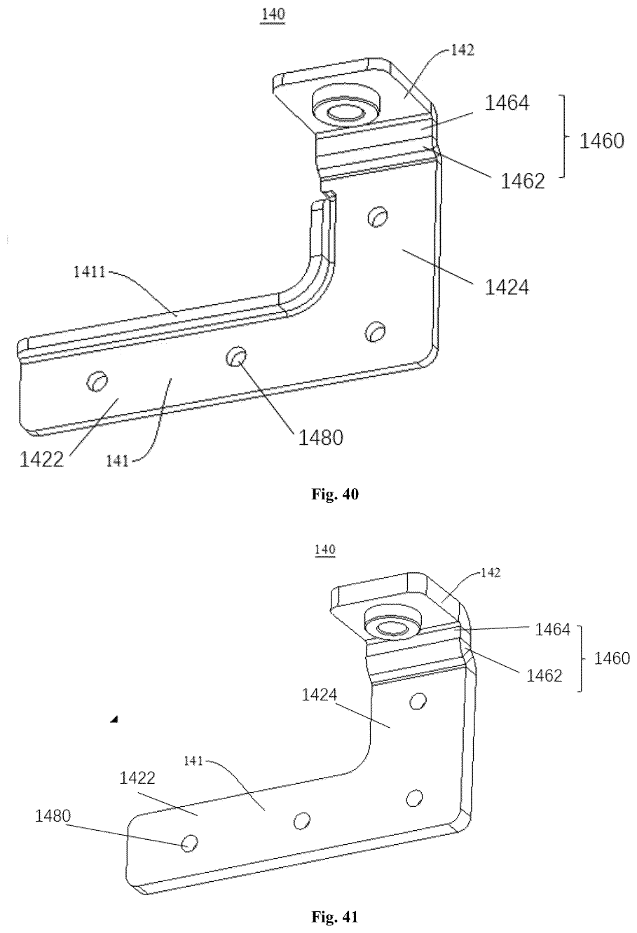

In an implementation, as shown in FIGS. 20, 40, 41 and 51-53, the connecting body 141 includes a first connecting portion 1422 extending in the first direction, and a second connecting portion 1424 connected between the first connecting portion 1422 and the extension 142, the second connecting portion 1424 extending in the second direction. For example, in the examples of FIGS. 40, 41 and 52, the connecting body 141 may be formed into a “7”-shaped structure, and the second connecting portion 1424 may be connected to an end of the first connecting portion 1422.

In this embodiment, by providing the above-mentioned first connecting portion 1422 and second connecting portion 1424, the dimension of the first connecting portion 1422 in the second direction is relatively small, which can reduce the overall space occupied by the connecting body 141 in the second direction; while the dimension of the second connecting portion 1424 in the first direction is relatively small, which can reduce the overall space occupied by the connecting body 141 in the first direction, thereby making the overall space occupied by the connecting body 141 smaller, providing clearance, and being conducive to the spatial layout of the circuit board 110.

In an implementation, as shown in FIG. 40, a reinforcing rib may be provided on the connecting body 141, and the reinforcing rib includes a flange 1411 provided at an edge of the connecting body 141 and bent towards a direction away from the circuit board 110. With such a configuration, the flange 1411 can effectively achieve an anti-bending effect, so that the connection between the connecting body 141 and the circuit board 110 is more secure, preventing the edge of the connecting body 141 from warping, thereby increasing the reliability.

In an implementation, with reference to FIGS. 53, 40 and 41, the connecting seat 1400 further includes a limiting portion 1460 connected between the connecting body 141 and the extension 142, the limiting portion 1460 and the circuit board 110 defining a clearance groove therebetween. For example, in the examples of FIGS. 53, 40 and 41, the clearance groove is defined by the limiting portion 1460 and the first surface of the circuit board 110 together. In this way, a wire harness can pass through the clearance groove, thereby effectively providing clearance for wiring while making the wiring neater.

In an implementation, as shown in FIGS. 53, 40 and 41, the limiting portion 1460 includes a first limiting sub-portion 1462 and a second limiting sub-portion 1464. The first limiting sub-portion 1462 is connected to the connecting body 141 and inclined relative to the circuit board 110. The second limiting sub-portion 1464 is connected between the first limiting sub-portion 1462 and the extension 142, the second limiting sub-portion 1464 being arranged at an angle relative to the extension 142. Preferably, the second limiting sub-portion 1464 is parallel to the circuit board 110.

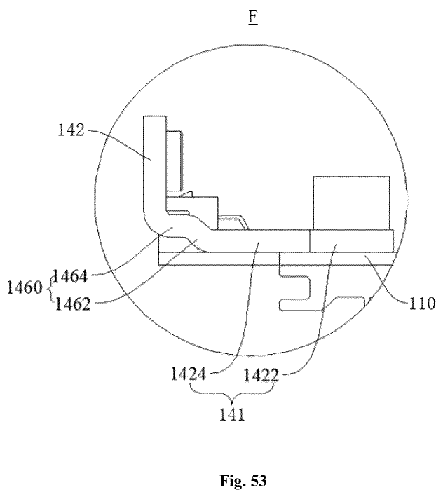

Exemplarily, in the example of FIG. 53, an end of the first limiting sub-portion 1462 (e.g., the right end in FIG. 53) is connected to an end of the second connecting portion 1424 away from the first connecting portion 1422 (e.g., the left end in FIG. 53), and the other end of the first limiting sub-portion 1462 (e.g., the left end in FIG. 53) extends inclinedly upward in a direction away from the heating components 112. An end of the second limiting sub-portion 1464 (e.g., the right end in FIG. 53) is connected to the other end of the first limiting sub-portion 1462 (e.g., the left end in FIG. 53), and the other end of the second limiting sub-portion 1464 (e.g., the left end in FIG. 53) extends horizontally in a direction away from the heating components 112.

In an implementation, as shown in FIG. 53, the extension 142 extends beyond an end of the circuit board 110 in the second direction. With such a configuration, the conductive connectors 280, 290 can be better in contact with a surface of a side of the extension 142 away from the heating components 112, which prevents the interference between the conductive connectors 280, 290 and the circuit board 110, and improves the reliability of connection between the conductive connectors 280, 290 and the extension 142, thereby enabling current to flow from the power supply module 270 through the conductive connectors 280, 290 and the connecting seat 1400 and then be input in the circuit board 110 to achieve power supply to the circuit board 110 by the power supply module 270.

In an implementation, with reference to FIGS. 40, 41 and 52, at least one positioning hole 1480 is formed on and passes through the connecting seat 1400 in a thickness direction. For example, in the examples of FIGS. 40, 41 and 52, four positioning holes 1480 are formed on each connecting seat 1400, and the four positioning holes 1480 are all located on the connecting body 141. The positioning holes 1480 may be a circular hole, but are not limited thereto. Thus, by providing the above-mentioned positioning holes 1480, during a welding process of the connecting seats 1400 and the circuit board 110, the positioning holes 1480 can be fitted with fixture positioning pins to define the degree of freedom of the connecting seats 1400, thereby effectively fixing the connecting seats 1400 and ensuring the assembly and manufacture accuracy of the connecting seats 1400.

In an implementation, a clearance groove 143 may be defined between the extension 142 and the first surface. For example, the clearance groove 143 is defined by the first connecting segment, the second connecting segment, and the first surface of the circuit board 110 together. In this way, a wire harness may pass through the clearance groove 143, thereby effectively providing clearance for wiring.

In an implementation, as shown in FIG. 40, the edge of the connecting body 141 has a flange 1411 extending in the direction away from the circuit board 110. With such a configuration, the flange 1411 may effectively achieve an anti-bending effect, so that the connection between the connecting body 141 and the circuit board 110 is more secure, preventing the edge of the connecting body 141 from warping, thereby increasing the reliability.

In an implementation, with reference to FIGS. 39A, 42 and 43, the first surface of the circuit board 110 is provided with a plurality of heating components 111, a sealing member 160 is provided between the first heat sink 123 and the circuit board 110, and the sealing member 160 is arranged close to the air inlet. For example, the sealing member 160 may be made of rubber. Thus, by providing the above-mentioned sealing member 160, the sealing performance of the first heat sink 123 and the circuit board 110 at the air inlet can be improved, preventing moisture from entering from the gap between the first heat sink 123 and the circuit board 110, thereby protecting the heating components 111 close to the air inlet, while avoiding air leakage.

In an implementation, in conjunction with FIGS. 39A, 42 and 43, the sealing member 160 includes a first sealing portion 161 and a second sealing portion 162. The first sealing portion 161 abuts against the edges of the circuit board 110 and the first heat sink 123 close to the air inlet, the second sealing portion 162 is arranged on a side surface of the first sealing portion 161 facing away from the air inlet, and the second sealing portion 162 is located at the gap between the first heat sink 123 and the circuit board 110. Exemplarily, the second sealing portion 162 divides the first sealing portion 161 into two portions, one portion of the first sealing portion 161 is at least in contact with the edge of the heat dissipation body 121 of the first heat sink 123, and the other portion of the first sealing portion 161 is at least in contact with the edge of the circuit board 110. An entrance is provided between the edge of the heat dissipation body 121 of the first heat sink 123 close to the air inlet and the edge of the circuit board 110 close to the air inlet, and the second sealing portion 162 extends through the entrance into the gap between the first heat sink 123 and the circuit board 110.

Thus, by providing the above-mentioned first sealing portion 161 and second sealing portion 162, the first sealing portion 161 has a good blocking effect to prevent moisture at the air inlet from being in direct contact with the heat dissipation body 121 of the first heat sink 123 or the circuit board 110, and the second sealing portion 162 has an effective sealing effect to further prevent the moisture from entering the gap between the first heat sink 123 and the circuit board 110, thereby further improving the sealing performance of the first heat sink 123 and the circuit board 110 at the air inlet.

In an implementation, in conjunction with FIGS. 45-51, the working assembly 100 may not be provided with the sealing member 160, thereby ensuring the heat dissipation performance of the entire working assembly 100.

In an implementation, as shown in FIGS. 39A and 44, the circuit board 110 and the heat sink 120 may be connected by connectors, for example, the connectors may be screws, elastic connectors, or the like.

In an implementation, as shown in FIGS. 39A and 44, the circuit board 110 and the heat sink 120 are connected by spring screws 170. The spring screw 170 includes a screw 172 and a spring 171 sleeved on the screw 172. The end of the spring 171 close to the circuit board 110 extends in the direction away from the circuit board 110. For example, in the examples of FIGS. 39A and 44, the tail of the spring 171 is folded in the direction away from the circuit board 110. Thus, since the end of the spring 171 is relatively sharp, with such a configuration, the end of the spring 171 can be prevented from scratching aluminum debris due to the contact between the end of the spring 171 and the surface of the circuit board 110, thereby preventing the circuit board 110 from being damaged, and improving the integrity and reliability of the circuit board 110.

According to embodiments of a second aspect of the present application, an electronic device 200, such as a computing device, as shown in FIG. 20, comprises the working assembly 100 according to any one of the above-mentioned embodiments of the first aspect of the present application.

The electronic device 200 according to embodiments of the present application, by using the above-mentioned working assembly 100, makes the structure of the connecting seat 1400 simpler to facilitate processing, while achieving the electrical connection between the power supply module 270 and the circuit board 110, which can effectively improve the assembly efficiency of the working assembly 100.

According to embodiments of a third aspect of the present application, an electronic device 200, such as a computing device, as shown in FIGS. 1-9A, comprises the working assembly 100 according to any one of the above-mentioned implementations of the first aspect of the present application.

The electronic device 200 according to embodiments of the present application, such as a computing device, by using the above-mentioned working assembly 100, can reduce the maximum temperature difference between the heating components 111 close to the air outlet and the heating components 111 close to the air inlet, thereby improving the temperature uniformity of the heating components 111.

In an implementation, with reference to FIGS. 1-9A, the electronic device 200 comprises a housing 210 and a fan assembly 220. A heat dissipation air duct having an air inlet and an air outlet is defined in the housing 210, at least one working assembly 100 is provided within the heat dissipation air duct, and the working assembly 100 comprises a circuit board 110 and a plurality of heat sinks 120. The plurality of heat sinks 120 are provided on at least one side of the circuit board 110. For example, both sides of the circuit board 110 may be provided with a heat sink 120. The surface of the circuit board 110 is parallel to a first direction from the air inlet to the air outlet. The fan assembly 220 is arranged on the side of the housing 210 close to the air inlet.

Exemplarily, FIG. 9A shows three working assemblies 100, and the three working assemblies 100 are arranged at intervals in the direction perpendicular to the surface of the circuit board 110. Each heat sink 120 may include a heat dissipation body 121 and a plurality of heat dissipation fins 122, wherein the plurality of heat dissipation fins 122 are arranged at intervals on one side surface of the heat dissipation body 121 in a second direction (e.g., the vertical direction in FIG. 9A), the second direction being perpendicular to the first direction, and the second direction being parallel to the surface of the circuit board 110.

The heat dissipation body 121 of the first heat sink 123 may be in contact with the heating components 111 on the first surface, the heat dissipation body 121 of the second heat sink 124 may be in contact with the second surface of the circuit board 110, and the heat generated by the heating components 111 during operation may be transferred to the first heat sink 123 and the second heat sink 124. A heat dissipation channel extending in the first direction may be defined between two adjacent heat dissipation fins 122 and the heat dissipation body 121. During the operation of the fan assembly 220, cold air enters from the air inlet, flows along the heat dissipation channels of the first heat sink 123 and the second heat sink 124 and exchanges heat with the first heat sink 123 and the second heat sink 124, and hot air after heat exchange flows out of the air outlet, thereby achieving heat dissipation of the working assembly 100.

By arranging the fan assembly 220 on the side of the housing 210 close to the air inlet, the fan assembly 220 and the air outlet are located on either side of the housing 210, in cases where some working assemblies 100 are damaged, it is only necessary to remove the damaged working assemblies 100 and take out the same from the air outlet, and then place working assemblies 100 in normal operation into the housing 210 through the air outlet for installation, without removing the fan assembly 220, so that the installation and detachment of the working assemblies 100 are more convenient, thereby effectively improving the inspection and replacement efficiency of the working assemblies 100.

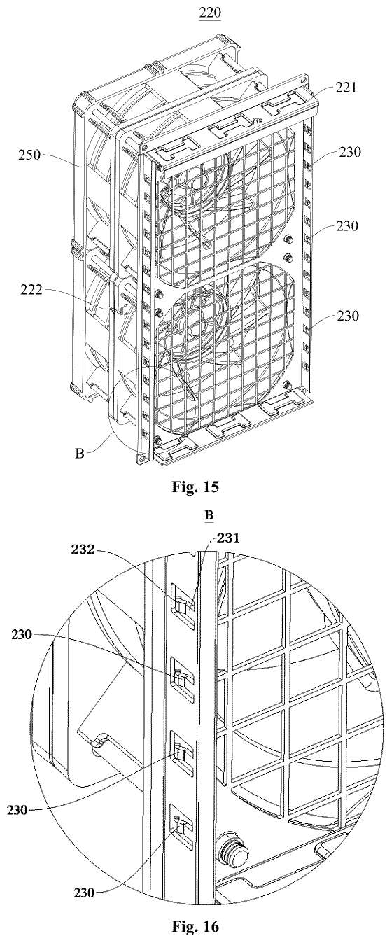

In an implementation, in conjunction with FIGS. 9A-15, the fan assembly 220 includes a mounting member 221 and a plurality of fan modules 222. The mounting member 221 is connected to the housing 210, and the plurality of fan modules 222 are connected to the side of the mounting member 221 facing away from the housing 210. For example, in the examples of FIGS. 15, 17 and 18, the outer profile dimension of the mounting member 221 is larger than that of the fan modules 222. A plurality of air inlet holes are formed on the portion of the mounting member 221 opposite the fan modules 222, and during the operation of the fan modules 222, under the action of the fan modules 222, external air enters the heat dissipation air duct through the plurality of air inlet holes, exchanges heat with the first heat sink 123 and the second heat sink 124, and then flows out of the air outlet.

Thus, by providing the above-mentioned mounting member 221 and the plurality of fan modules 222, the mounting member 221 may securely fix the fan modules 222 on the housing 210, thereby improving the structural stability and reliability of the entire electronic device 200. The plurality of fan modules 222 may increase the ventilation volume of the heat dissipation air duct, reduce the air resistance, and suppress dust accumulation on the heat sink 120, thereby effectively improving the heat dissipation effect of the working assembly 100.

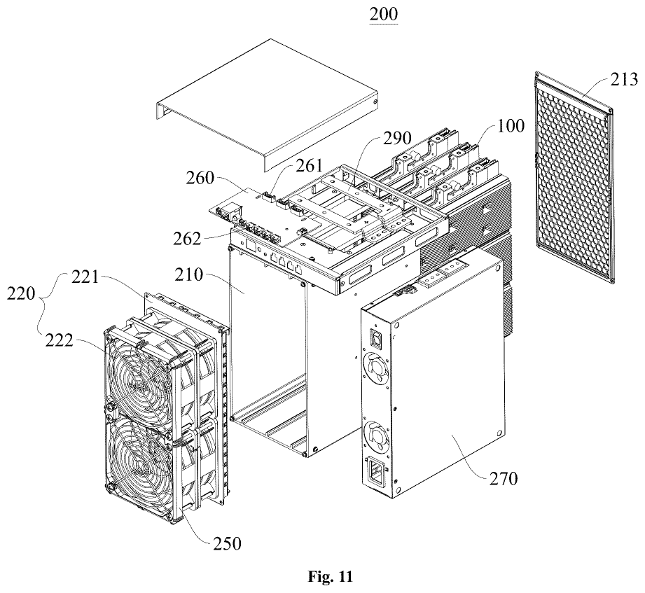

In an implementation, as shown in FIGS. 11 and 14-16, the mounting member 221 is provided with at least one first elastic component, and the first elastic component is pressed between the mounting member 221 and the corresponding side wall of the housing 210 to achieve secure installation between the mounting member 221 and the housing 210, thereby preventing the mounting member 221 from detaching from the housing 210.

In an implementation, as shown in FIGS. 11, 14-16, the mounting member 221 includes a mounting body, a mounting top plate and a mounting bottom plate which are oppositely arranged, two mounting side plates, and a first bending portion. The fan modules 222 are connected to the mounting body, and a plurality of air inlet holes are formed on the mounting body. The mounting top plate and the mounting bottom plate are arranged on the side of the mounting body facing away from the fan modules, the mounting top plate is connected to the upper portion of the mounting body, and the mounting bottom plate is connected to the lower portion of the mounting body. The two mounting side plates are arranged on the side of the mounting body facing away from the fan modules 222, the two mounting side plates are respectively connected to either side of the mounting body, and the first elastic component is provided on at least one of the two mounting side plates. The first bending portion is connected to the end of the mounting top plate facing away from the mounting body.

Exemplarily, in conjunction with FIGS. 11 and 13-16, the mounting top plate, the mounting bottom plate and the mounting side plates may all be perpendicular to the mounting body. The mounting top plate is connected between the mounting body and the first bending portion, and the first bending portion is parallel to the mounting body. After installation, the working assembly 100 may abut against the first bending portion. In this way, on one hand, there is a certain gap between the mounting member 221 and the working assembly 100 in the first direction, and thus when external air enters the heat dissipation air duct from the fan modules 222, the external air may uniformly flow at the gap between the mounting member 221 and the working assembly 100, and then flow through the first heat sink 123 and the second heat sink 124, thereby improving the heat dissipation effect. On the other hand, the first bending portion can achieve an effective air blocking effect, so that the air entering from the air inlet flows into the working assembly 100 as far as possible, thereby avoiding loss of air volume.

The mounting top plate and the mounting bottom plate may be provided with a plurality of I-shaped reinforcing ribs to avoid bending and warping of the mounting top plate and the mounting bottom plate, and improve the structural strength of the entire mounting member 221, thereby ensuring that the structure of the electronic device 200 is stable.

In an implementation, the at least one first elastic component includes a plurality of first elastic snaps 230 arranged at intervals in a vertical direction, wherein the free ends of the first elastic snaps are pressed between the mounting side plate and the corresponding side wall of the housing.

Exemplarily, a plurality of via holes arranged at intervals in a vertical direction may be formed on the mounting side plates, and the plurality of first elastic snaps 230 are provided in the plurality of via holes correspondingly on a one-to-one basis. One end of each first elastic snap 230 is connected to the edge of the corresponding via hole, and the other end (i.e., the above free end) of each first elastic snap 230 extends in the direction opposite to the first direction. When the mounting member 221 is mounted on the housing 210, the side walls of the housing 210 press the other end of each first elastic snap 230, enabling each first elastic snap 230 to elastically deform. When the mounting member 221 is detached from the housing 210, the first elastic snap 230 returns to its original shape. Each first elastic snap 230 is made of metal.

In one example, as shown in FIG. 16, each first elastic snap 230 may include a connecting portion 231 and an abutting portion 232. One end of the connecting portion 231 is connected to a first edge of the corresponding via hole. One end of the abutting portion 232 is connected to the other end of the connecting portion 231, the other end of the abutting portion 232 is spaced apart from the opposite edge of the first edge, and the abutting portion 232 abuts against the corresponding side wall of the housing 210.

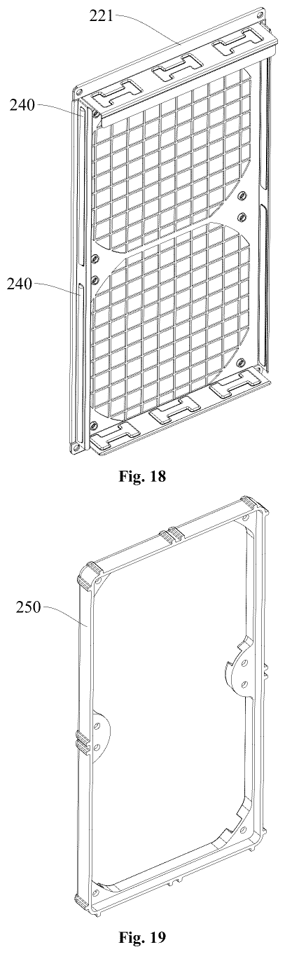

Thus, the mounting member 221 and the housing 210 may be electrically connected by a plurality of first elastic snaps 230, thereby achieving effective shielding and grounding effects, and improving the safety of the electronic device 200. In another implementation, with reference to FIG. 18 and in conjunction with FIG. 11, the at least one first elastic component includes a first conductive foam 240 extending in a vertical direction, and the mounting member 221 are in elastic contact with the corresponding side wall of the housing 210 by the first conductive foam 240. For example, the first conductive foam 240 may be adhered to the two mounting side plates by an adhesive. Optionally, the first conductive foam 240 may be conductive, but is not limited thereto. In this way, the mounting member 221 and the housing 210 may be electrically connected by the first conductive foam 240, thereby also achieving effective shielding and grounding effects, and improving the safety of the electronic device 200.

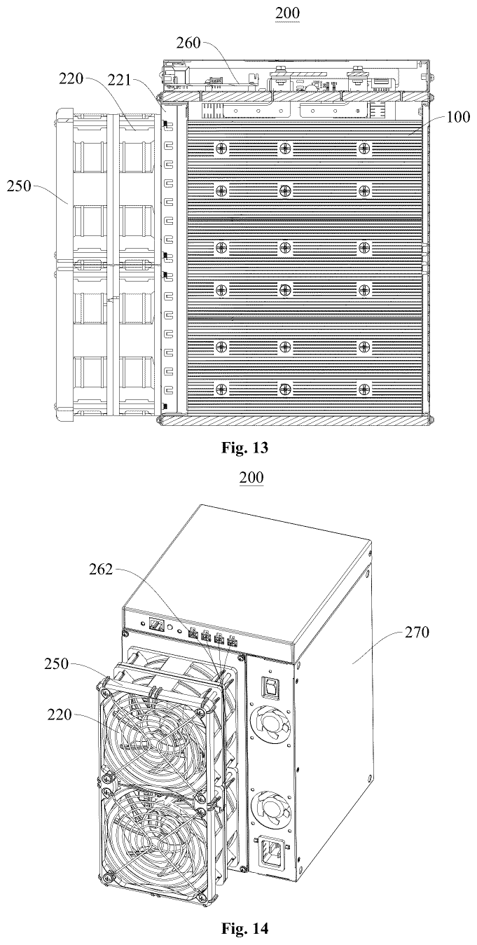

In an implementation, as shown in FIG. 13, the fan modules 222 are spaced apart from the working assembly 100 in the first direction. For example, in the example of FIG. 13, there is a certain gap between the mounting 221 and the working assembly 100 in the first direction. When external air enters the heat dissipation air duct from the fan modules 222, the air may uniformly flow at the gap between the mounting member 221 and the working assembly 100, and then flow through the first heat sink 123 and the second heat sink 124. Thus, the gap between the fan modules 222 and the working assembly 100 can enable more uniform airflow into the heat sink 120, thereby improving the heat dissipation effect.

In an implementation, with reference to FIGS. 14-19, a flexible protective cover 250 is provided on the side of the fan module 222 far away from the mounting plate, and the flexible protective cover 250 is sleeved on the periphery of the fan module 222. Thus, the flexible protective cover 250 configured in this way can effectively protect the corners of the fan module 222, avoid wear of the fan module 222, and prevent the corners of the fan module 222 from scratching a worker, thereby improving the safety. Optionally, the flexible protective cover 250 may be made of a soft adhesive material, but is not limited thereto.

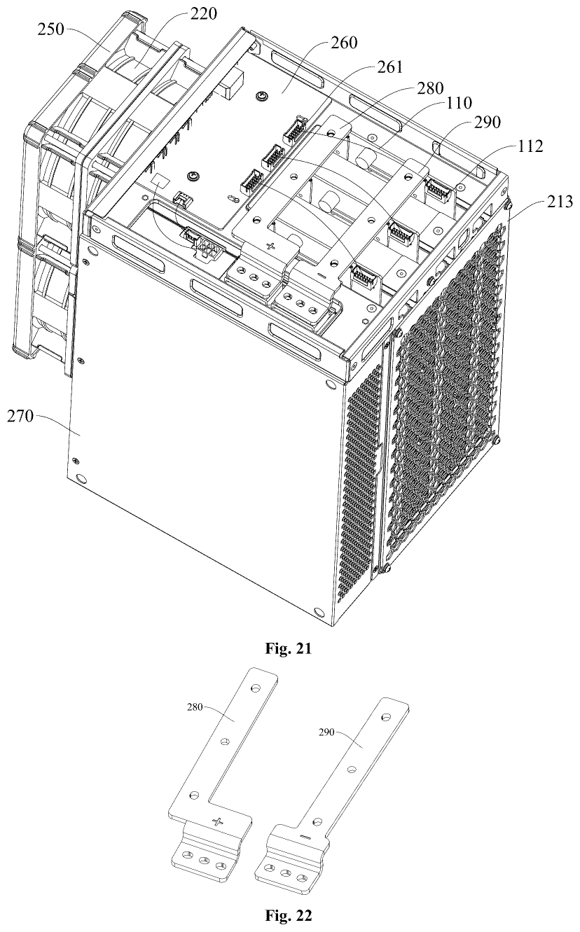

In an implementation, as shown in FIGS. 20 and 21, a control board 260 is provided at the top of the housing 210, the control board 260 is provided with a plurality of fan interfaces 262, and the plurality of fan interfaces 262 are connected to the plurality of fan modules 222 correspondingly on a one-to-one basis, wherein all the plurality of fan interfaces 262 are arranged close to the air inlet, so that the plurality of fan interfaces 262 are arranged close to the plurality of fan modules 222, thereby facilitating wiring between the plurality of fan interfaces 262 and the plurality of fan modules 222.

Exemplarily, the circuit board 110 is provided with a first signal socket 112, the control board 260 is provided with a second signal socket 261, and the second signal socket 261 is connected to the first signal socket 112. For example, in the examples of FIGS. 20 and 21, there are three second signal sockets, and the three second signal sockets 261 may be connected by means of three first cables to the circuit boards 110 of three working assemblies 100 correspondingly on a one-to-one basis, allowing the control board 260 to control the operation of the circuit boards 110.

Exemplarily, the second signal socket 261 is close to the first signal socket 112. Exemplarily, when the number of second signal sockets 261 is three, the number of first signal sockets 112 is three, wherein the three second signal sockets 261 are arranged on the side of the control board 260 close to the first signal sockets 112. Such a configuration can facilitate the connection between the second signal sockets 261 and the first signal sockets 112 by using shortest connection lines.

Exemplarily, there are four fan interfaces 262 and four fan modules 222, and the four fan interfaces 262 may be connected by means of four second cables to the four fan modules 222 correspondingly on a one-to-one basis, allowing the control board 260 to control the operation of the fan modules.

Exemplarily, the four fan modules 222 are divided into two groups, and the two fan modules 222 in each group are connected by screws and are fixed on the mounting member 221 by the screws. Through holes are provided at the four corners of each fan module 222, allowing the screws to pass through, and corresponding threaded holes 2211 are provided on the mounting member 221, allowing the screws to pass through, thereby achieving the assembly of the fan modules 222 and the mounting member. Exemplarily, the mounting member 221 is further provided with a plurality of fixing holes 2212 for fixing the mounting member 221 on the housing 210. For example, four fixing holes 2212 are provided at the four corners of the mounting member 221, and corresponding fixing holes are provided on the housing 210.

Thus, with such a configuration, on one hand, signal connection between the control board 260 and the fan module 222 and signal connection between the control board 260 and the circuit board 110 can be achieved. On the other hand, by arranging the plurality of fan interfaces 262 close to the air inlet, the plurality of fan interfaces 262 can be arranged on the control board 260 in a centralized manner, so that the structure is more compact and the occupied space is smaller, thereby facilitating control of the space layout of other modules on the control board 260.

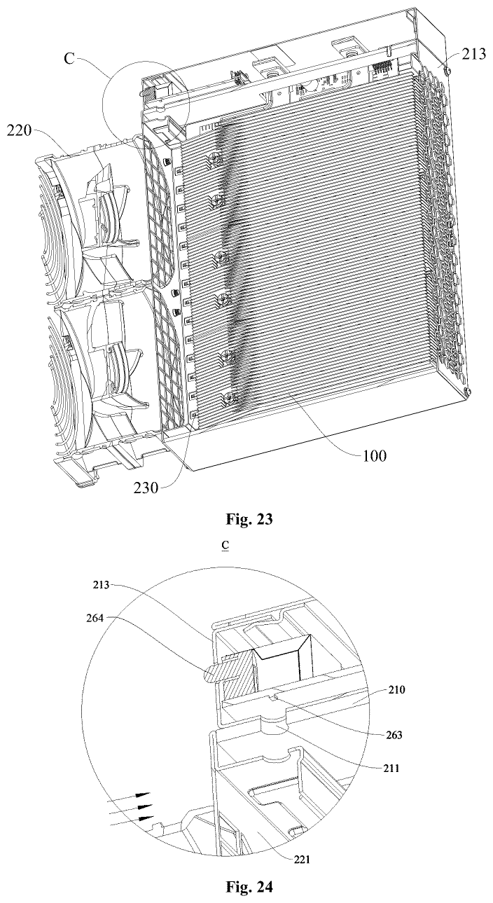

In an implementation, with reference to FIGS. 23-25B, a top shell 212 is provided at the top of the housing 210, the control board 260 is provided within the top shell 212, and the control board 260 is provided with a temperature sensor 263, the temperature sensor 263 being used for sensing the temperature at the air inlet. In this way, a user can know the temperature at the air inlet in real time to prevent the temperature of the air entering from the air inlet from being too high, so that the working assembly 100 has a good heat dissipation effect, thereby ensuring normal operation of the working assembly 100, and effectively prolonging the service life of the entire electronic device 200.

In an implementation, as shown in FIGS. 23 and 24, the temperature sensor 263 is provided at the bottom of the control board 260, and the temperature sensor 263 is located within the top shell 212. A vent hole 211 in communication with the heat dissipation air duct is formed on the top surface of the housing 210, and the vent hole 211 corresponds to the position of the temperature sensor 263. For example, in the examples of FIGS. 23 and 24, a first vent hole passing through the thickness of the mounting member 221 is formed at the top thereof, and the first vent hole, the vent hole 211, and the temperature sensor 263 correspond to each other in a vertical direction.

Thus, the temperature sensor 263 in the above-mentioned implementation may sense the temperature at the air inlet through the vent hole 211, thereby ensuring that the air entering from the air inlet is cold air. Furthermore, the temperature sensor 263 may be hidden in the top shell 212, preventing the temperature sensor 263 from in direct contact with the external environment, so that the top shell 212 can effectively protect the temperature sensor 263, prevent damage to the temperature sensor 263, and make the appearance of the electronic device 200 more neat and beautiful.

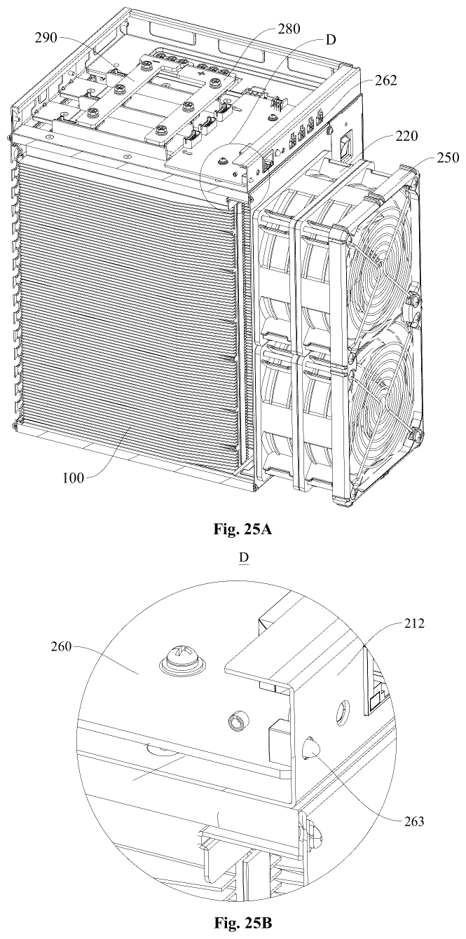

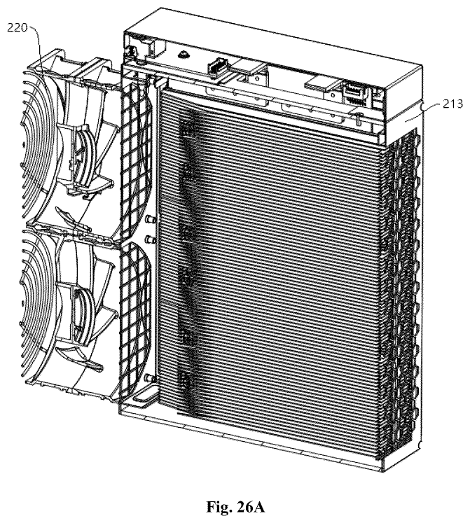

In another implementation, with reference to FIGS. 25A and 25B, the temperature sensor 263 is provided at the top of the control board 260, and the temperature sensor 263 extends from the side surface of the top shell 212 close to the fan assembly 220. For example, in the examples of FIGS. 25A and 25B, a through hole may be formed on the side surface of the top shell 212 close to the air inlet, the temperature sensor 263 may be provided on the side of the control board 260 close to the air inlet, and the temperature sensor 263 extends out of the top shell 212 through the through hole. With such a configuration, the temperature sensor 263 can directly extend out of the top shell 212 to sense the temperature at the air inlet, without the need to provide holes on the housing 210 and the mounting member 221, so that the structure of the housing 210 is simpler, facilitating processing.

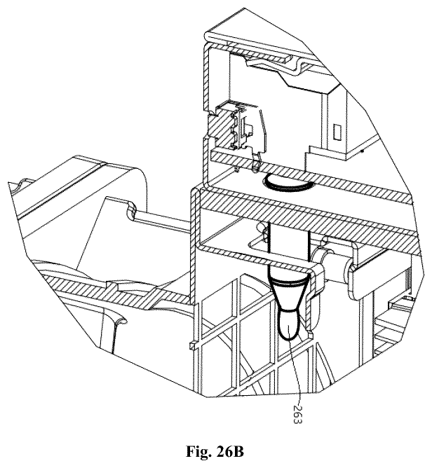

Of course, the present application is not limited thereto. In yet another implementation, as shown in FIGS. 26A and 26B, the free end of the temperature sensor 263 may pass through the top of the housing 210 into the housing 210 and is opposite to the fan assembly 220. In this way, the free end of the temperature sensor 263 can extend into an air inlet cavity of the housing 210 to detect the temperature of the air input by the fan assembly 220, so that the temperature at the air inlet can be sensed more accurately.

During the implementation of the present invention, the inventor finds that an indicator lamp of the electronic device 200 is typically provided in the middle of the control board of the electronic device 200, and when a plurality of fans (e.g., four fans) are connected in series and are mounted on the front end surface of the electronic device 200, due to the angle of view, the fans may block the indicator lamp, which affects the observation of operation and maintenance personnel, especially when the electronic device 200 needs to be placed on a rack and sometimes the position thereof is high, the indicator lamp may be more liable to be blocked by the fans.

On this basis, In an implementation, as shown in FIGS. 23 and 24, the electronic device 200 may further include an indicator lamp 264 to indicate the operation state of the electronic device 200. The indicator lamp 264 is arranged on the side of the control board close to the air inlet, and the indicator lamp 264 is located at the end of the side of the control board close to the air inlet.

Since the indicator lamp 264 is arranged at the end of the side of the control board, the indicator lamp can be observed from one side of the electronic device 200, thereby preventing the fans from blocking the indicator lamp.

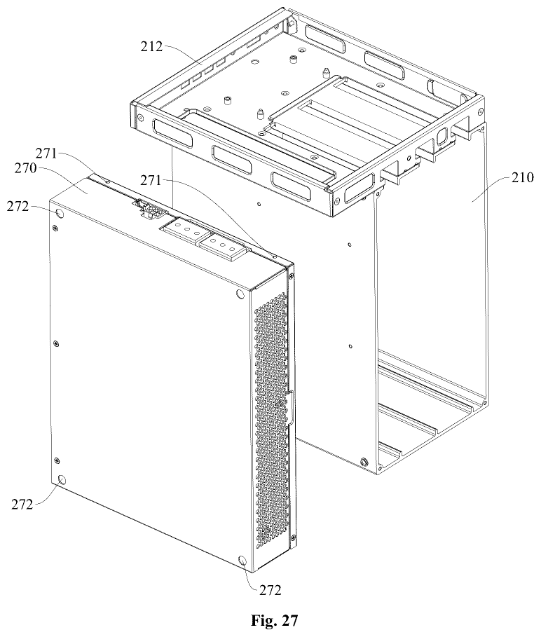

In an implementation, as shown in FIGS. 27-29B, the electronic device 200 further comprises: a power supply module 270, the power supply module 270 being provided on one side of the housing 210 in the third direction, and the power supply module 270 being used for supplying power to the circuit board 110 and the fan assembly 220, wherein the third direction is perpendicular to the surface of the circuit board 110.

Exemplarily, the housing 210 generally has a cuboid structure, and the housing 210 may include a top surface, a bottom surface and four side surfaces, wherein the four side surfaces are connected between the top surface and the bottom surface. The top surface and the bottom surface are opposite to each other in the second direction. The top of the power supply module 270 is connected to the top shell 212, and the side surfaces of the power supply module 270 are connected to the side surfaces of the housing 210.

In the third direction, the top shell 212 includes two first side surfaces which are oppositely arranged and two second side surfaces which are oppositely arranged, wherein one of the two first side surfaces is flush with the corresponding fourth side surface of the housing 210, the other of the two first side surfaces is flush with the corresponding side surface of the power supply module 270, each second side surface is flush with the corresponding side surfaces of the housing 210 and the power supply module 270, and the bottom surface of the power supply module 270 is flush with the bottom surface of the housing 210.

Specifically, for example, the two first side surfaces of the top shell 212 may be the front side surface and the rear side surface, respectively, and the two second side surfaces of the top shell 212 may be the left side surface and the right-side surface, respectively. The front side surface of the top shell 212 may be flush with the front side surface of the housing 210 and the front side surface of the power supply module 270, the rear side surface of the top shell 212 may be flush with the rear side surface of the housing 210 and the rear side surface of the power supply module 270, the left side surface of the top shell 212 may be flush with the left side surface of the housing 210, the right side surface of the top shell 212 may be flush with the right side surface of the power supply module 270, and the bottom surface of the power supply module 270 is flush with the bottom surface of the housing 210.

It should be noted that the above-mentioned “front” refers to the direction close to the air inlet of the heat dissipation air duct, and the opposite direction is defined as “rear”, i.e., the direction close to the air outlet of the heat dissipation air duct. “Left” refers to the direction from the power supply module 270 towards the housing 210; and “right” refers to the direction from the housing 210 towards the power supply module 270. Accordingly, “front side surface” refers to the side surface close to the air inlet of the heat dissipation air duct, and “rear side surface” refers to the side surface close to the air outlet of the heat dissipation air duct. “Left side surface” refers to the side surface in the direction from the power supply module 270 facing the housing 210, and “right side surface” refers to the side surface in the direction from the housing 210 facing the power supply module 270.

Thus, by means of the above-mentioned power supply module 270, the power supply module 270 can effectively utilize the space between the top shell 212 and the housing 210 while supplying power to the circuit board 110 and the fan assembly 220, so that the structure of the whole electronic device 200 is more compact.

In an implementation, as shown in FIGS. 27-30B, at least one positioning hole 271 is formed on one of the power supply module 270 and the top shell 212, at least one positioning protrusion is formed on the other of the power supply module 270 and the top shell 212, and the positioning protrusion is fitted into the corresponding positioning hole 271. At least one through hole 272 is formed on one of the power supply module 270 and the housing 210, at least one threaded hole corresponding to the through hole 272 is formed on the other of the power supply module 270 and the housing 210, and the threaded fastener 273 is adapted to passing through the through hole 272 to be in threaded connection with the threaded hole.

For example, in the examples of FIGS. 27-30B, two positioning holes 271 are formed at the top of the power supply module 270, with the two positioning holes 271 being spaced apart in the first direction, and correspondingly, two positioning protrusions spaced apart in the first direction may be provided on the bottom surface of the top shell 212, and the two positioning protrusions correspond to the two positioning holes 271 on a one-to-one basis. Four through holes 272 are formed on the side surface of the power supply module 270, and the four through hole 272 are respectively located at the four corners of the power supply module 270. Four threaded holes corresponding to the four through holes 272 on a one-to-one basis are formed on the second side surface of the housing 210. During installation, the two positioning protrusions may be respectively fitted into the corresponding positioning holes 271 to position the power supply module 270. Then, four threaded fasteners 273 respectively pass through the corresponding through holes 272 to be in threaded connection with the corresponding threaded holes to fix the power supply module 270.

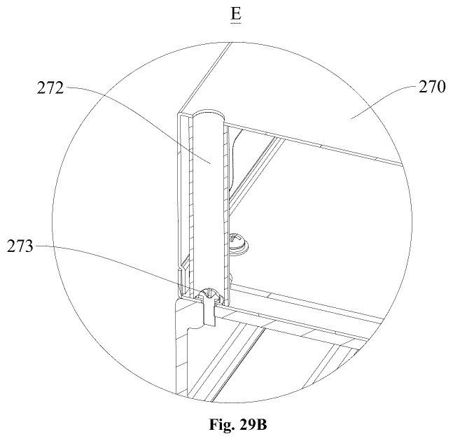

In one example, as shown in FIGS. 29A and 29B, the threaded fasteners 273 may be short screws. In this case, the threaded fasteners 273 may pass through one side wall of the power supply module 270 to be in threaded connection with the threaded holes on the housing 210, and at this time, the one side wall of the power supply module 270 is pressed between the heads of the threaded fasteners 273 and the housing 210.

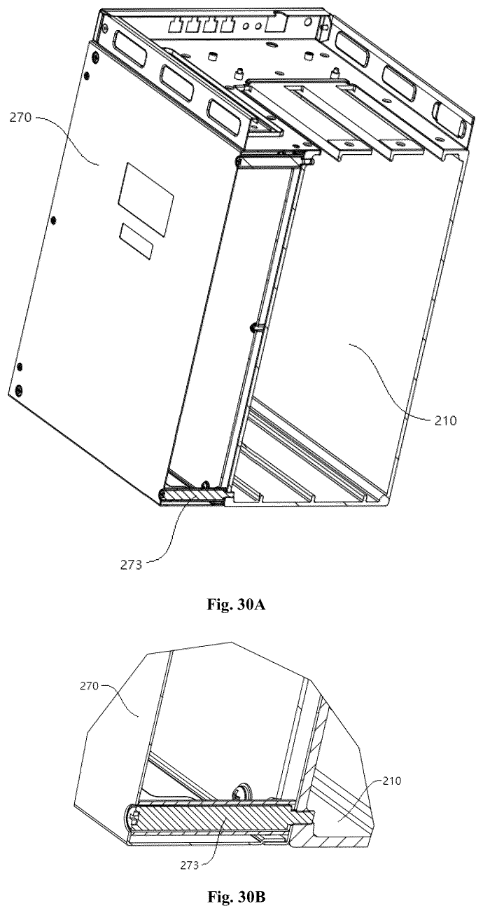

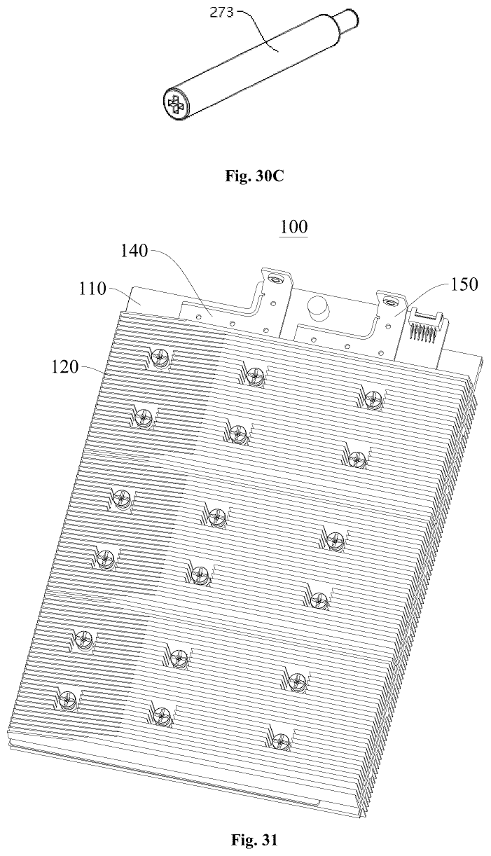

In another example, as shown in FIGS. 30A-30C, the threaded fasteners 273 may be long screws. In this case, the threaded fastener 273 may pass through two side walls of the power supply module 270 to be in threaded connection with the threaded holes on the housing 210, and at this time, the entire power supply module 270 is pressed between the heads of the threaded fasteners 273 and the housing 210. This fixing method provides better visibility, facilitating installation and disassembly of the threaded fasteners 273 such as screws.

Of course, it is also possible that some of the threaded fasteners 273 are short screws, and other threaded fasteners 273 are long screws, which are not limited in the present application.

Thus, the power supply module 270 may be positioned relative to the housing 210 in advance by the fitting of the positioning protrusions and the positioning holes 271 to avoid displacement of the power supply module 270 during the process of positioning relative to the housing 210, thereby improving the installation efficiency. Furthermore, the power supply module 270 and the housing 210 may be in direct threaded connection by the threaded fasteners 273, without the need to provide a bracket between the power supply module 270 and the housing 210, thereby simplifying the structure.

In an implementation, with reference to FIGS. 20-22, the electronic device 200 further includes a first conductive connector 280 and a second conductive connector 290. Specifically, a portion of the first conductive connector 280 is electrically connected to the power supply module 270, and another portion of the first conductive connector 280 is electrically connected to the first connecting seat 140 of the working assembly 100. A portion of the second conductive connector 290 is electrically connected to the power supply module 270, and another portion of the second conductive connector 290 is electrically connected to the second connecting seat 150 of the working assembly 100.

For example, in the examples of FIGS. 20-22, the bottom surface of said another portion of the first conductive connector 280 may be in contact with the top surfaces of the third connecting segments of three first connecting seats 140. First fasteners are adapted to passing through the first conductive connector 280 to be connected to the third connecting segments of the corresponding first connecting seats 140. The bottom surface of said another portion of the second conductive connector member 290 may be in contact with the top surfaces of the second connecting segments of the three second connecting seats 150, and second fasteners are adapted to passing through the second conductive connector member 290 to be connected to the third connecting segments of the corresponding second connecting seats 150. Said another portion of the first conductive connector 280 may be parallel to said another portion of the second conductive connector 290, both of which extending in the third direction. The first conductive connector 280 may be a positive bus bar, and the second conductive connector 290 may be a negative bus bar.

Thus, by providing the above-mentioned first conductive connector 280 and second conductive connector 290, electrical connection between the power supply module 270 and the circuit board 110 can be achieved, so that current can be input into the circuit board 110 from the power supply module 270, thereby achieving power supply for the circuit board 110. Furthermore, the structures of the first conductive connector 280 and the second conductive connector 290 are simple and convenient to arrange.

In an implementation, as shown in FIGS. 9A-10B, an air outlet panel 213 is provided at the air outlet of the housing 210, at least one second elastic component is provided at the edge of the air outlet panel 213, and the second elastic component is pressed between the air outlet panel 213 and the corresponding side wall of the housing 210. Thus, by providing the above-mentioned second elastic component, the second elastic component may be compressed into the housing 210, so that the connection between the air outlet panel 213 and the housing 210 is more stable, thereby preventing the air outlet panel 213 from detaching from the housing 210.

In an implementation, the air outlet panel 213 includes an air outlet body, an air outlet top plate and an air outlet bottom plate which are oppositely arranged, two air outlet side plates and a second bending portion. A plurality of air outlet holes are formed on the air outlet body, the air outlet top plate and the air outlet bottom plate are provided on one side surface of the air outlet body, the air outlet top plate is connected to the upper portion of the air outlet body, and the air outlet bottom plate is connected to the lower portion of the air outlet body. The two air outlet side plates are provided on one side surface of the air outlet body, and the two air outlet side plates are respectively connected to either side of the air outlet body. The second elastic component is provided on at least one of the two air outlet side plates, the second bending portion is connected to the end of the air outlet top plate far away from the air outlet body, and the second bending portion is located between the air outlet top plate and the air outlet bottom plate.

Exemplarily, the air outlet bottom plate and the air outlet side plates may all be perpendicular to the air outlet body. The air outlet top plate is connected between the air outlet body and the second bending portion. After installation, the working assembly 100 may abut against the second bending portion, so that the air flowing through the first heat sink 123 and the second heat sink 124 can better flow out through the air outlet holes, thereby further improving the heat dissipation effect.

In one example, as shown in FIGS. 9A and 9B, the above at least one second elastic component includes a plurality of second elastic snaps 214 arranged at intervals in the second direction, wherein each second elastic snap 214 is pressed between the air outlet panel 213 and the corresponding side wall of the housing 210.

For example, a plurality of spacing grooves arranged at intervals in a vertical direction may be formed on the air outlet side plates, and the portions of the air outlet side plates located between two adjacent spacing grooves are the second elastic snaps 214. During installation, the two air outlet side plates are compressed into the corresponding side walls of the housing 210, and at this time, the plurality of second elastic snaps 214 elastically deform, and then the air outlet panel 213 is in threaded connection with the housing 210 by threaded fasteners. During detachment, it is only necessary to remove the thread fasteners and then pull out the air outlet panel 213, and at this time, the plurality of second elastic snaps 214 return to their original shape.

In another example, the above at least one second elastic component includes a second conductive foam 215 extending in the second direction. With such a configuration, the air outlet panel 213 and the housing 210 may be electrically connected by the second conductive foam 215 while achieving secure connection between the air outlet panel 213 and the housing 210, thereby achieving effective shielding and grounding effects, and further improving the safety of the electronic device 200.

In an implementation, at least one blocking piece is provided at the top of the housing 210, and the blocking piece corresponds to the position of the heat sink 120. In this way, the air blown out by the fan modules 222 can be uniformly blown to a plurality of heat sinks 120 to prevent a part of air from blowing into the top shell 212 at the top of the housing 210, thereby increasing the ventilation volume in the heat dissipation air duct, preventing dust accumulation on the heat sinks 120, and further improving the heat dissipation effect.

In the description of the present description, it should be understood that orientations or position relationships indicated by terms such as “central”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axially”, “radially”, and “circumferentially” are orientations or position relationships based on those illustrated in the accompanying drawings, which are only used for conveniently describing the present application and simplifying the description, rather than indicating or implying that the device or element referred to must have a particular orientation, and be constructed and operated in the particular orientation, and therefore should not be understood as limitations to the present application.

Furthermore, terms such as “first” and “second” are used for the purpose of illustration only, and should not be understood as indicating or implying relative importance or implicitly specifying the number of indicated technical features. Thus, the features defined by “first” and “second” may explicitly or implicitly include one or more of the features.

In the present application, unless specified or defined otherwise, terms such as “installation”, “linking”, “connecting”, “fixing”, etc. should be understood broadly, which may be, for example, fixed connection, detachable connection, or integrally formed. It may be mechanical connection, electrical connection, or communication connection. It may be direct connection, indirect connection by an intermediate medium, internal communication between two elements, or interaction between two elements. For those skilled in the art, the specific meanings of the above-mentioned terms in the present application may be understood according to specific situations.

In the present application, unless specified or limited otherwise, a first feature being “above” or “below” a second feature may include the first feature being in direct contact with the second feature, and may also include the first feature and the second feature are not in direct contact with each other but being in contact with each other by another feature therebetween. Furthermore, the first feature being “on”, “above” and “over” the second feature may include the first feature being directly or obliquely above the second feature, or just means that the height of the first feature is higher than that of the second feature. The first feature being “below”, “under” and “beneath” the second feature may include the first feature being directly or obliquely below the second feature, or just means that the height of the first feature is lower than that of the second feature.

The above disclosure provides various different implementations or examples for implementing different structures of the present application. In order to simplify the disclosure of the present application, components and arrangements of specific examples are described above. Of course, they are merely examples and are not intended to limit the application. In addition, reference numerals and/or letters may be repeated in various examples in the present application for the purpose of simplicity and clarity, which does not indicate relationships between various implementations and/or arrangements discussed.

The above description merely relates to specific implementations of the present application, but the scope of protection of the present application is not limited thereto. Any person skilled in the art would have been readily conceived of various modifications or replacements without departing from the technical scope disclosed in the present application, and these modifications or replacements shall fall within the scope of protection of the present application. Therefore, the scope of protection of the present application shall be based on the scope of protection of said claims.

What is claimed is:

1. An electrical connecting seat for a computing device, wherein the computing device comprises a working assembly and a power supply module, the working assembly comprises at least one circuit board, the electrical connecting seat is arranged at an edge of a first surface of the circuit board, and a plurality of powered components are further arranged on the first surface; and
wherein the electrical connecting seat is used for taking power from the power supply module to supply power to the plurality of powered components.

2. The electrical connecting seat according to claim 1, wherein the electrical connecting seat comprises:
a connecting body electrically connected to the circuit board; and
an extension electrically connected to a conductive connector, wherein the conductive connector is further electrically connected to the power supply module.

3. The electrical connecting seat according to claim 1, wherein a connecting body of the electrical connecting seat is attached to the first surface of the circuit board; and
there is an angle between an extension direction of an extension of the electrical connecting seat and the first surface.

4. The electrical connecting seat according to claim 1, wherein an angle between an extension direction of an extension of the electrical connecting seat and the first surface is a right angle.

5. The electrical connecting seat according to claim 1, wherein the computing device further comprises a heat dissipation air duct extending along a first direction and located between an air inlet and an air outlet, and the working assembly is arranged within the heat dissipation air duct; and
a second direction is perpendicular to the first direction, and the first surface is parallel to the first direction and the second direction.

6. The electrical connecting seat according to claim 1, wherein the first surface is parallel to a first direction and a second direction, and the first direction is perpendicular to the second direction; and
at least part of a connecting body of the electrical connecting seat extends along the second direction, and an extension of the electrical connecting seat extends along a third direction that is perpendicular to the first direction and the second direction.

7. The electrical connecting seat according to claim 6, wherein a dimension of the connecting body of the electrical connecting seat in the second direction is greater than a dimension of the extension of the electrical connecting seat in the third direction.

8. The electrical connecting seat according to claim 6, wherein a dimension of the at least part of the connecting body of the electrical connecting seat in the first direction is equal to a dimension of the extension of the electrical connecting seat in the first direction.

9. The electrical connecting seat according to claim 1, wherein a projection of an extension of the electrical connecting seat onto a plane, where the first surface is located, is located beyond the first surface.

10. The electrical connecting seat according to claim 1, wherein the electrical connecting seat comprises:
a connecting body electrically connected to the circuit board;
an extension electrically connected to a conductive connector, wherein the conductive connector is further electrically connected to the power supply module; and
a transitional connecting segment connecting the connecting body and the extension.

11. The electrical connecting seat according to claim 1, wherein a projection of a transitional connecting segment of the electrical connecting seat onto a plane, where the first surface is located, is located beyond the first surface.

12. The electrical connecting seat according to claim 1, wherein at least one positioning hole is formed on and passes through a connecting body of the electrical connecting seat along a thickness direction, and the positioning hole is used for passing a fastener to fixedly connect the connecting seat to the circuit board.

13. The electrical connecting seat according to claim 1, wherein at least one connecting hole is formed on and passes through an extension of the electrical connecting seat along a thickness direction, and the at least one connecting hole is used for passing a fastener to form an electrical connection between the electrical connecting seat and the power supply module.

14. The electrical connecting seat according to claim 1, wherein a material of the electrical connecting seat is copper or aluminum.

15. The electrical connecting seat according to claim 1, wherein a number of the electrical connecting seat is two, which are a positive electrical connecting seat for being electrically connected to a positive power supply end of the power supply module and a positive power connection end of the circuit board, and a negative electrical connecting seat for being electrically connected to a negative power supply end of the power supply module and a negative power connection end of the circuit board, respectively.

16. The electrical connecting seat according to claim 15, wherein the positive electrical connecting seat and the negative electrical connecting seat are arranged in parallel in an extension direction of an edge of the circuit board.

17. A working assembly, comprising the electrical connecting seat according to claim 1.

18. The working assembly according to claim 17, wherein an edge of the first surface of the circuit board is provided with a signal module electrically connected to a control panel of the computing device and at least part of the powered components, respectively, for receiving a data signal from the control panel and sending the data signal to the at least part of the powered components.

19. The working assembly according to claim 17, further comprising:
a heat sink arranged on the circuit board for performing heat dissipation for at least part of the powered components.

20. An electronic device, comprising a power supply module and the working assembly according to claim 17.
